(19) United States
(12) Patent Application Publication
(10) Pub. No.: US 2025/0147839 A1
(43) Pub. Date: May 8, 2025

(54) MEMORY SYSTEM AND DECODING METHOD FOR THE SAME

(71) Applicant: SK hynix Inc., Gyeonggi-do (KR)

(72) Inventors: Bi Woong CHUNG, Gyeonggi-do (KR); Dae Sung KIM, Gyeonggi-do (KR)

(21) Appl. No.: 18/813,037

(22) Filed: Aug. 23, 2024

(30) Foreign Application Priority Data
Nov. 7, 2023 (KR) 10-2023-0152691

(51) Int. Cl. G06F 11/10

(52) U.S. Cl. CPC G06F 11/1004; G06F 11/1068

(57) ABSTRACT

A method for decoding a memory system, the method may include establishing a plurality of check nodes and a plurality of variable nodes corresponding to the plurality of check nodes of a codeword; setting a preliminary operation speed based on a progress rate of a preliminary operation for generating predictive error information of each of the plurality of the variable nodes; performing the preliminary operation according to the preliminary operation speed; and performing a main decoding operation for error correction on at least a part of the plurality of the variable nodes based on the predictive error information.

### CROSS-REFERENCE TO RELATED APPLICATIONS

This patent application claims priority under 35 U.S.C. § 119 (e) of Korean Patent Application No. 10-2023-0152691, filed on Nov. 7, 2023, the entire disclosure of which is incorporated herein by reference.

### TECHNICAL FIELD

Various embodiments of the present disclosure described herein relate to a memory system, and more particularly, to an apparatus and a method for improving a speed of an error correction operation in the memory system.

### BACKGROUND

A data processing system, including a communication system, a memory system, or a data storage device, has been developed to store more data in a memory device and transfer data stored in data storage devices more quickly. The memory device may include nonvolatile memory cells and/or volatile memory cells for storing data.

Various communication systems and data processing systems may present high requirements for complexity and performance of low-density parity-check (LDPC) decoders. A bit flipping decoder may be suitable for such applications. Column layered scheduling may be a way to increase convergence speed and may improve error correction performance. Further, layered decoding may lead to improved decoding performance with low computational complexity in LDPC decoder implementations.

### SUMMARY

An embodiment of the present disclosure may provide a memory device, a memory system, a controller included in the memory system, a data processing system including the memory system or the memory device, or a communication system for transmitting data.

In an embodiment of the present disclosure, a method for decoding a memory system may comprise establishing a plurality of check nodes and a plurality of variable nodes corresponding to the plurality of check nodes of a codeword; setting a preliminary operation speed based on a progress rate of a preliminary operation for generating predictive error information of each of the plurality of the variable nodes; performing the preliminary operation according to the preliminary operation speed; and performing a main decoding operation for error correction on at least a part of the plurality of the variable nodes based on the predictive error information. establishing a plurality of check nodes and a plurality of variable nodes corresponding to the plurality of check nodes of a codeword; setting a preliminary operation speed based on a progress rate of a preliminary operation for generating predictive error information of each of the plurality of the variable nodes; performing the preliminary operation according to the preliminary operation speed; and performing a main decoding operation for error correction on at least a part of the plurality of the variable nodes based on the predictive error information.

The setting of the preliminary operation speed may include differently setting the number of the variable nodes, on which the preliminary operation is performed during a unit time, according to the progress rate of the preliminary operation.

The progress rate of the preliminary operation may include the number of iterations of the preliminary operation and an execution order of a plurality of sub-preliminary operations included in the preliminary operation.

In another embodiment of the present disclosure, a memory system may comprise a memory device configured to output a codeword read from a plurality of memory cells; and a controller configured to set a preliminary operation speed, based on a progress rate of the preliminary operation for generating predictive error information of each of a plurality of the variable nodes, perform the preliminary operation according to the preliminary operation speed, and perform a main decoding operation for error correction on at least a part of the plurality of the variable nodes based on the predictive error information.

The controller may include a preliminary operation unit including a plurality of unit preliminary operation units for performing the preliminary operation, and sets the preliminary operation speed by varying the number of a plurality of unit preliminary operation units driven during a unit time.

The progress rate of the preliminary operation may include the number of iterations of the preliminary operation and an execution order of a plurality of sub-preliminary operations included in the preliminary operation.

### BRIEF DESCRIPTION OF THE DRAWINGS

The description herein makes reference to the accompanying drawings wherein like reference numerals refer to like parts throughout the figures.

FIG. 1 describes a data processing system according to an embodiment of the present disclosure.

FIG. 2 describes a low-density parity-check (LDPC) code according to another embodiment of the present disclosure.

FIG. 3 describes a communication system according to another embodiment of the present disclosure.

FIG. 4 describes an LDPC decoder according to an embodiment of the present disclosure.

FIG. 5 describes an LDPC decoding method according to another embodiment of the present disclosure.

FIG. 6 describes an LDPC decoder according to another embodiment of the present disclosure.

FIG. 7 describes a first example of operations performed by the main operation unit described in FIG. 6.

FIG. 8 describes a second example of operations performed by the main operation unit described in FIG. 6.

FIG. 9 describes a third example of operations performed by the main operation unit described in FIG. 6.

FIG. 10 describes a fourth example of operations performed by the main operation unit described in FIG. 6.

FIG. 11 describes a first example of operations performed by the preliminary operation unit described in FIG. 6.

FIG. 12 describes a second example of operations performed by the preliminary operation unit described in FIG. 6.

FIG. 13 describes a third example of operations performed by the preliminary operation unit described in FIG. 6.

FIG. 14 describes an LDPC decoder according to another embodiment of the present disclosure.

FIG. 15 describes an operation of the LDPC decoder described with reference to FIG. 14.

FIGS. 16A and 16B describe an operation of a speed setting unit described with reference to FIG. 14.

FIG. 17 illustrates a preliminary operation unit described with reference to FIG. 14.

FIG. 18 illustrates a parity check matrix.

FIG. 19 illustrates the structure of speed information in accordance with an embodiment of the present disclosure.

FIG. 20 illustrates the structure of speed information in accordance with an embodiment of the present disclosure.

FIG. 21 illustrates an execution time of a preliminary operation varying depending on a progress rate of the preliminary operation.

FIGS. 22A to 22C describe energy consumed by the LDPC decoder according to a progress rate of an operation.

### DETAILED DESCRIPTION

Various embodiments of the present disclosure are described below with reference to the accompanying drawings. Elements and features of this disclosure, however, may be configured or arranged differently to form other embodiments, which may be variations of any of the disclosed embodiments.

In this disclosure, references to various features (e.g., elements, structures, modules, components, steps, operations, characteristics, etc.) included in “one embodiment,” “example embodiment,” “an embodiment,” “another embodiment,” “some embodiments,” “various embodiments,” “other embodiments,” “alternative embodiment,” and the like are intended to mean that any such features are included in one or more embodiments of the present disclosure, but may or may not necessarily be combined in the same embodiments.

In this disclosure, the terms “comprise,” “comprising,” “include,” and “including” are open-ended. As used in the appended claims, these terms specify the presence of the stated elements and do not preclude the presence or addition of one or more other elements. The terms in a claim do not foreclose the apparatus from including additional components e.g., an interface unit, circuitry, etc.

In this disclosure, various units, circuits, or other components may be described or claimed as “configured to” perform a task or tasks. In such contexts, “configured to” is used to connote structure by indicating that the blocks/units/circuits/components include structure (e.g., circuitry) that performs one or more tasks during operation. As such, the block/unit/circuit/component may be said to be configured to perform the task even when the specified block/unit/circuit/component is not currently operational e.g., is not turned on nor activated. The block/unit/circuit/component used with the “configured to” language include hardware for example, circuits, memory storing program instructions executable to implement the operation, etc. Additionally, “configured to” may include a generic structure e.g., generic circuitry, that is manipulated by software and/or firmware e.g., an FPGA or a general-purpose processor executing software to operate in manner that is capable of performing the task(s) at issue. “Configured to” may also include adapting a manufacturing process e.g., a semiconductor fabrication facility, to fabricate devices e.g., integrated circuits that are adapted to implement or perform one or more tasks.

As used in this disclosure, the term ‘machine,’ ‘circuitry’ or ‘logic’ refers to all of the following: (a) hardware-only circuit implementations such as implementations in only analog and/or digital circuitry and (b) combinations of circuits and software and/or firmware, such as (as applicable): (i) to a combination of processor(s) or (ii) to portions of processor(s)/software including digital signal processor(s), software, and memory(ies) that work together to cause an apparatus, such as a mobile phone or server, to perform various functions and (c) circuits, such as a microprocessor(s) or a portion of a microprocessor(s), that require software or firmware for operation, even if the software or firmware is not physically present. This definition of ‘machine,’ ‘circuitry’ or ‘logic’ applies to all uses of this term in this application, including in any claims. As a further example, as used in this application, the term ‘machine,’ ‘circuitry’ or ‘logic’ also covers an implementation of merely a processor or multiple processors or portion of a processor and its (or their) accompanying software and/or firmware. The term ‘machine,’ ‘circuitry’ or ‘logic’ also covers, for example, and if applicable to a particular claim element, an integrated circuit for a storage device.

As used herein, the terms ‘first,’ ‘second,’ ‘third,’ and so on are used as labels for nouns that they precede, and do not imply any type of ordering e.g., spatial, temporal, logical, etc. The terms ‘first’ and ‘second’ do not necessarily imply that the first value must be written before the second value. Further, although the terms may be used herein to identify various elements, these elements are not limited by these terms. These terms are used to distinguish one element from another element that otherwise have the same or similar names. For example, a first circuitry may be distinguished from a second circuitry.

Further, the term ‘based on’ is used to describe one or more factors that affect a determination. This term does not foreclose additional factors that may affect a determination. That is, a determination may be solely based on those factors or based, at least in part, on those factors. Consider the phrase “determine A based on B.” While in this case, B is a factor that affects the determination of A, such a phrase does not foreclose the determination of A from also being based on C. In other instances, A may be determined based solely on B.

Embodiments will now be described with reference to the accompanying drawings, wherein like numbers reference like elements.

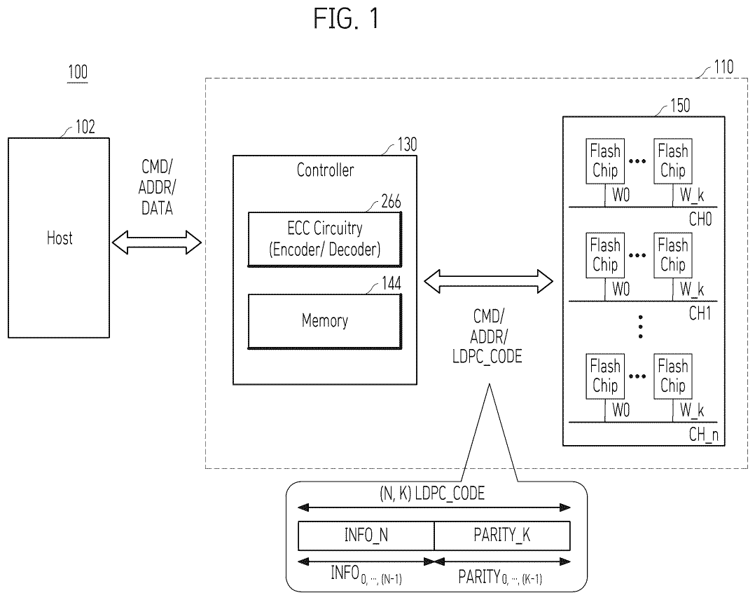

FIG. 1 describes a data processing system 100 according to an embodiment of the present disclosure.

Referring to FIG. 1, the data processing system 100 may include a host 102 engaged or coupled with a memory system 110. For example, the host 102 and the memory system 110 may be coupled to each other via a data bus, a host cable, and the like to perform data communication.

The memory system 110 may include a memory device 150 and a controller 130. The memory device 150 and the controller 130 in the memory system 110 may be considered components or elements physically separated from each other. The memory device 150 and the controller 130 may be connected via at least one data path. For example, the data path may include a channel and/or a way.

According to an embodiment, the memory device 150 and the controller 130 may be components or elements functionally divided. Further, according to an embodiment, the memory device 150 and the controller 130 may be implemented with a single chip or a plurality of chips.

The controller 130 may perform a data input and output (input/output) operation (such as a read operation, a program operation, an erase operation, etc.) in response to a request or a command input from an external device such as the host 102. For example, when the controller 130 performs a read operation in response to a read request input from an external device, data stored in a plurality of non-volatile memory cells included in the memory device 150 are transferred to the controller 130. Further, the controller 130 may independently perform an operation regardless of the request or the command input from the host 102. Regarding an operation state of the memory device 150, the controller 130 may perform an operation such as garbage collection (GC), wear leveling (WL), a bad block management (BBM) for checking whether a memory block is bad and handing a bad block.

The memory device 150 may include plural memory chips coupled to the controller 130 through plural channels CH0, CH1, . . . , CH1_n and ways W0, . . . , W_k. The memory chip may include a plurality of memory planes or a plurality of memory dies. According to an embodiment, the memory plane may be considered a logical or a physical partition including at least one memory block, a driving circuit capable of controlling an array including a plurality of non-volatile memory cells, and a buffer that may temporarily store data inputted to, or outputted from, non-volatile memory cells. Each memory plane or each memory die may support an interleaving mode in which plural data input/output operations are performed in parallel or simultaneously. According to an embodiment, memory blocks included in each memory plane, or each memory die, included in the memory device 150 may be grouped to input/output plural data entries as a super memory block. An internal configuration of the memory device 150 shown in the above drawing may be changed based on operating performance of the memory system 110. An embodiment of the present disclosure may not be limited to the internal configuration described in FIG. 1.

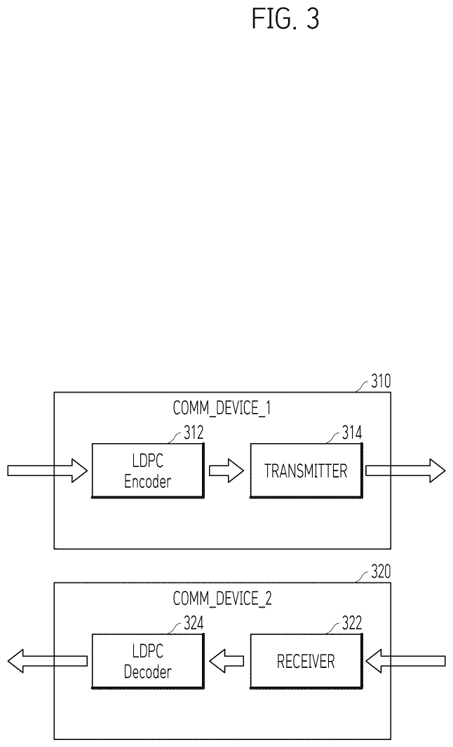

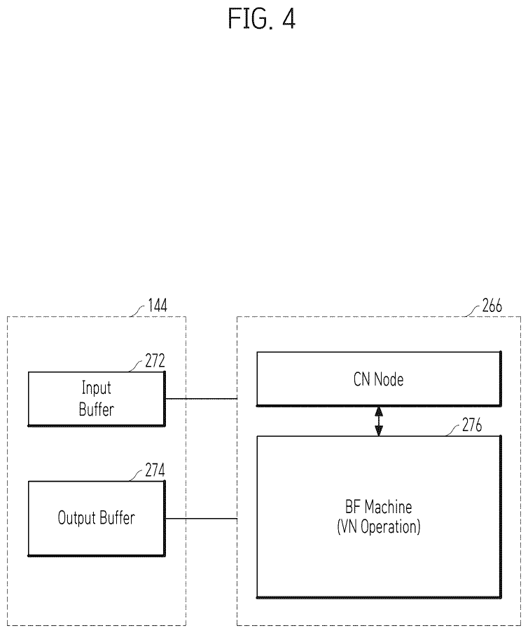

The controller 130 may control a program operation or a read operation performed within the memory device 150 in response to a write request or a read request entered from the host 102. According to an embodiment, the controller 130 may execute firmware to control the program operation or the read operation in the memory system 110. Herein, the firmware may be referred to as a flash translation layer (FTL). An example of the FTL will be described in detail, referring to FIGS. 3 and 4. According to an embodiment, the controller 130 may be implemented with a microprocessor, a central processing unit (CPU), an accelerator, or the like. According to an embodiment, the memory system 110 may be implemented with at least one multi-core processor, co-processors, or the like.

The memory 144 may serve as a working memory of the memory system 110 or the controller 130, while temporarily storing transactional data for operations performed in the memory system 110 and the controller 130. According to an embodiment, the memory 144 may be implemented with a volatile memory. For example, the memory 144 may be implemented with a static random access memory (SRAM), a dynamic random access memory (DRAM), or both. The memory 144 may be disposed within the controller 130, embodiments are not limited thereto. The memory 144 may be located within or external to the controller 130. For instance, the memory 144 may be embodied by an external volatile memory having a memory interface transferring data and/or signals between the memory 144 and the controller 130.

According to an embodiment, the controller 130 may further include error correction code (ECC) circuitry 266 configured to perform error checking and correction of data transferred between the controller 130 and the memory device 150. The ECC circuitry 266 may be implemented as a separate module, circuit, or firmware in the controller 130, but may also be implemented in each memory chip included in the memory device 150 according to an embodiment. The ECC circuitry 266 may include a program, a circuit, a module, a system, or an apparatus for detecting and correcting an error bit of data processed by the memory device 150.

According to an embodiment, the ECC circuitry 266 may include an error correction code (ECC) encoder and an ECC decoder. The ECC encoder may perform error correction encoding of data to be programmed in the memory device 150 to generate encoded data into which a parity bit is added, and store the encoded data in the memory device 150. The ECC decoder may detect and correct error bits contained in the data read from the memory device 150 when the controller 130 reads the data stored in the memory device 150. For example, after performing error correction decoding on the data read from the memory device 150, the ECC circuitry 266 may determine whether the error correction decoding has succeeded or not, and output an instruction signal, e.g., a correction success signal or a correction fail signal, based on a result of the error correction decoding. The ECC circuitry 266 may use a parity bit, which has been generated during the ECC encoding process for the data stored in the memory device 150, in order to correct the error bits of the read data entries. When the number of the error bits is greater than or equal to the number of correctable error bits, the ECC circuitry 266 may not correct the error bits and instead may output the correction fail signal indicating failure in correcting the error bits. According to an embodiment, the ECC circuitry 266 may perform an error correction operation based on a coded modulation such as a low density parity check (LDPC) code, a Bose-Chaudhuri-Hocquenghem (BCH) code, a turbo code, a Reed-Solomon (RS) code, a convolution code, a recursive systematic code (RSC), a trellis-coded modulation (TCM), a Block coded modulation (BCM), or the like. The ECC circuitry 266 may include all circuits, modules, systems, and/or devices for performing the error correction operation based on at least one of the above-described codes.

According to an embodiment, the controller 130 and the memory device 150 may transmit and receive a command CMD, an address ADDR, or a codeword. For example, the codeword (N, K) LDPC_CODE may include (N+K) bits or symbols.

According to an embodiment, the codeword may include LDPC_CODE. The codeword (N, K) LDPC_CODE may include an information word INFO_N and a parity PARITY_K. The information word INFO_N may include N bits or symbols INFO₀, . . . , INFO_{(N-1)}, and the parity PARITY_K may include K bits or symbols PARITY₀, . . . , PARITY_{(K-1)}. Here, N and K are natural numbers and may vary depending on a design of the LDPC code.

For example, if an input information word INFO_N including N bits or symbols INFO₀, . . . , INFO_{(N-1)} is LDPC-encoded, a codeword (N, K) LDPC_CODE may be generated. The codeword (N, K) LDPC_CODE may include (N+K) bits or symbols LDPC_CODE₀, . . . , LDPC_CODE_{(N+K)-1}. The LDPC code may be a type of linear block code. A linear block code may be described by a generator matrix G or a parity check matrix H. As a feature of this LDPC code, most of the elements (e.g., entries) of the parity check matrix are made of 0, and the number of non-zero elements thereof is small as compared to a code length, so that iterative decoding based on probability could be possible. For instance, a first proposed LDPC code could be defined by a parity check matrix having a non-systematic form. The parity check matrix may be designed to have a uniformly low weight in its rows and columns. Here, a weight indicates the number of 1s included in a column or row of the parity check matrix.

For example, regarding all codewords (N, K) LDPC_CODE, characteristics of a linear code may satisfy Equation 1 or Equation 2 shown below.

$$LDPC\_CODE \cdot {H}^{7} = O \qquad ( Equation 1 )$$

$$H \cdot {LDPC\_CODE}^{T} = [ \begin{matrix}{h}_{1} & {h}_{2} & {h}_{3} & … & h \text{?}\end{matrix} ] \cdot {LDPC\_CODE}^{T} = \text{?} {LDPC\_CODE}_{i} - \text{?} = 0 \qquad ( Equation 2 )$$

$$\text{?} \text{indicates text missing or illegible when filed}$$

In Equations 1 and 2, H denotes a parity check matrix, LDPC_CODE denotes a codeword, LDPC_CODEi denotes the i-th bit of the codeword, and (N+K) denotes a length of the codeword. Also, hi indicates an i-th column of the parity check matrix H. The parity check matrix H may include (N+K) columns equal to the number of bits of the LDPC codeword. Equation 2 shows that the sum of the products of the i-th column hi of the parity check matrix H and the i-th codeword bit LDPC_CODEi is ‘0’, so the i-th column hi would be related to the i-th codeword bit LDPC_CODEi.

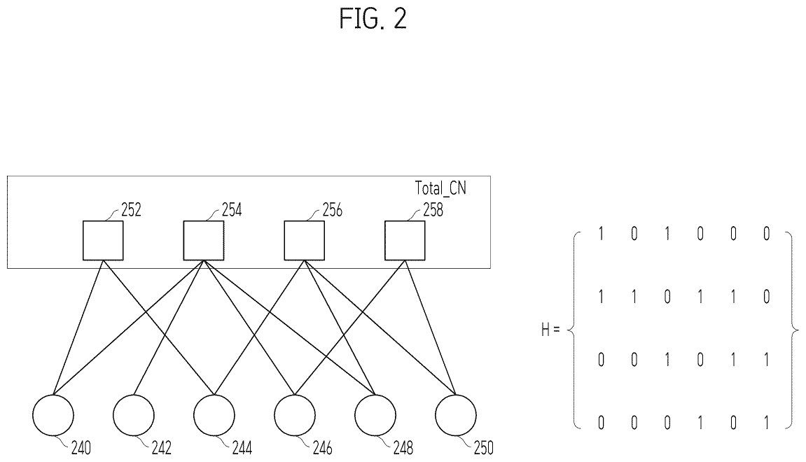

FIG. 2 describes a LDPC code according to another embodiment of the present disclosure.

FIG. 2 shows an example of a parity check matrix H of an LDPC code, which has 4 rows and 6 columns, and a Tanner graph thereof. Referring to FIG. 2, because the parity check matrix H has 6 columns, a codeword having a length of 6-bits may be generated. The codeword generated through H becomes an LDPC codeword, and each column of the parity check matrix H may correspond to each of 6 bits in the codeword.

Referring to FIG. 2, the Tanner graph of the LDPC code encoded and decoded based on the parity check matrix H may include 6 variable nodes 240, 242, 244, 246, 248, 250 and 4 check nodes 252, 254, 256, 258. Here, the i-th column and the j-th row of the parity check matrix H of the LDPC code correspond to the i-th variable node and the j-th check node, respectively. In addition, a value of 1 at the intersection of the j-th column and the j-th row of the parity check matrix H of the LDPC code (i.e., the meaning of the value other than 0) means that there is an edge connecting the i-th variable node and the j-th check node on the Tanner graph as shown in FIG. 2.

The degree of the variable node and the check node in the Tanner graph of the LDPC code means the number of edges (i.e., lines) connected to each node. The number of edges could be equal to the number of non-zero entries (e.g., 1s) in a column or row corresponding to the node in the parity check matrix of the LDPC code. For example, in FIG. 2, degrees of the variable nodes 240, 242, 244, 246, 248, 250 are 2, 1, 2, 2, 2, 2 in order, respectively. Degrees of the check nodes 252, 254, 256, 258 are 2, 4, 3, 2 in order, respectively. In addition, the number of non-zero entries in each column of the parity check matrix H of FIG. 2, corresponding to the variable nodes of FIG. 2, may coincide with the above-mentioned orders 2, 1, 2, 2, 2, 2 in order. The number of non-zero entries in each row of the parity check matrix H of FIG. 2, corresponding to the check nodes of FIG. 2, may coincide with the aforementioned orders 2, 4, 3, 2 in order.

The LDPC code may be used for a decoding process using an iterative decoding algorithm based on a sum-product algorithm on a bipartite graph listed in FIG. 2. Here, the sum-product algorithm is a type of message passing algorithm. The message passing algorithm may include operations or processes for exchanging messages through an edge on the bipartite graph and calculating and updating an output message from the messages input to a variable node or a check node.

Herein, a value of the i-th coded bit may be determined based on a message of the i-th variable node. Depending on an embodiment, the value of the i-th coded bit may be obtained through both a hard decision and a soft decision. Therefore, performance of the i-th bit ci of the LDPC codeword may correspond to performance of the i-th variable node of the Tanner graph, which may be determined according to positions of 1s and the number of 1s in the i-th column of the parity check matrix. In other words, performance of (N+K) codeword bits of a codeword may be influenced by the positions of 1s and the number of 1s in the parity check matrix, which means that the parity check matrix may greatly affect performance of the LDPC code. Therefore, a method for designing a good parity check matrix would be required to design an LDPC code with excellent performance.

According to an embodiment, for ease of implementation, a quasi-cyclic LDPC (QC-LDPC) code using a QC parity check matrix may be used as a parity check matrix. The QC-LDPC code is characterized by having a parity check matrix including zero matrices having a form of a small square matrix or circulant permutation matrices. In this case, the permutation matrix may be a matrix in which all entries of the square matrix are 0 or 1 and each row or column includes only one 1. Further, the cyclic permutation matrix may be a matrix obtained by circularly shifting each of the entries of the permutation matrix from the left to the right.

FIG. 3 describes a communication system according to an embodiment of the present disclosure.

Referring to FIG. 3, the communication system may selectively include a first communication device 310 for transmitting signals or data and a second communication device 320 for receiving signals or data. The first communication device 310 may include an LDPC encoder 312 and a transmitter 314. The second communication device 320 may include a receiver 322 and an LDPC decoder 324. Herein, the LDPC encoder 312 and the LDPC decoder 324 may encode or decode signals or data based on the LDPC code described in FIG. 2.

Referring to FIGS. 1 and 3, components used for encoding or decoding signals or data based on the LDPC code may be implemented within the memory system 110 including the controller 130, the communication system including the communication devices 310, 320, or the data processing system 110 including the memory system 110, based on an operation, a configuration, and performance thereof.

According to an embodiment, when a decoding process is performed using a sum-product algorithm (SPA), an LDPC code may provide performance close to capacity performance. For hard-decision decoding, a bit flipping (BF) algorithm based on an LDPC code has been proposed. A BF algorithm may flip a bit, symbol, or group of bits (e.g., change ‘0’ to ‘1’, or vice versa) based on a value of a flipping function (FF) computed at each iteration or each iterative operation. The flipping function associated with the variable node VN could be a reliability metric of the corresponding bit decision and may depend on a binary value (checksum) of the check node CN connected to the variable node VN. The BF algorithm could be simpler than the sum-product algorithm (SPA), but the simpleness may make a difference in performance. To reduce this performance difference, various types of BF algorithms have been proposed. The BF algorithm may be designed to improve the flipping function, which is the reliability metric of the variable node VN, and/or the method of selecting bits, symbols, or groups of bits to be flipped, thereby providing various degrees of bit error rate (BER) in response to reduction or increment of complexity or improving convergence rate performance.

FIG. 4 describes an LDPC decoder according to an embodiment of the present disclosure.

Referring to FIGS. 1 and 4, the controller 130 may include the memory 144 and the ECC circuitry 266. The ECC circuitry 266 may include an LDPC decoder. The LDPC decoder may include a bit flipping (BF) machine 276. The codeword (N, K) LDPC_CODE transferred from the memory device 150 may include the information word INFO_N and the parity PARITY_K. The information word INFO_N may include N bits or symbols INFO₀, . . . , INFO_{(N-1)}, and the parity PARITY_K may include K bits or symbols PARITY₀, . . . , PARITY_{(K-1)}.

According to an embodiment, the LDPC decoder may establish a plurality of the variable nodes VN and a plurality of check nodes CN. The number of the variable nodes VN is proportional to the length (N+K) of the codeword (N, K) LDPC_CODE. The plurality of the variable nodes VN may be stored in an SRAM in the memory 144. The plurality of check nodes CN is proportional to the length K of the parity PARITY_K, and the plurality of the variable nodes VN may be stored in registers. The registers may be used for storing relatively small size data, as compared to SRAM. There are almost no restrictions regarding the amount of access to data stored at the same time (e.g., memory width), as compared to SRAM. Also, the register may have an advantage of lower power consumption than SRAM, when a small storage capacity is required and an amount of data access (e.g., memory width) is large. The ECC circuitry 266 may be configured to receive a plurality of the variable nodes VN from an input buffer 272 in the memory 144, perform a decoding process through bit flipping, and store a result of the decoding process in an output buffer 274.

The BF machine 276 may be configured to compare a value for each variable node VN, which is calculated based on a flip function (FF) for calculating reliability of a current value bit using the number of unsatisfied check nodes UCN or channel information, with a threshold value and determine whether bit flipping (correction of 0 to 1 or 1 to 0) is performed based on a comparison result.

Referring to FIGS. 1 to 4, the codeword (N, K) LDPC_CODE transmitted from the memory device 150 to the controller 130 may include an error for various reasons. For example, an error occurs in a process of transmitting data through a data path (e.g., channel, way, etc.) from the memory device 150 to the controller 130 or transmitting the codeword (N, K) LDPC_CODE from the controller 130 to the memory device 150. In addition, as an integration degree of non-volatile memory cells in the memory device 150 increases and the number of bits of data stored in each non-volatile memory cell increases, an error may occur while the memory device 150 programs data into non-volatile memory cells or reads data stored in non-volatile memory cells. To detect and correct these errors, the ECC circuitry 266 in controller 130 may perform hard-decision decoding and/or soft-decision decoding. When performing soft-decision decoding based on a generalized LDPC (GLDPC) such as a Belief Propagation (BP) algorithm, the ECC circuitry 266 may provide good performance, but complexity due to an increased amount of computation performed to achieve great performance may make implementation of the controller 130 difficult. However, the complexity could be reduced by applying the BF algorithm to the hard-decision decoding.

The BP algorithm for decoding LDPC codes may update all variable nodes VN and check nodes CN in parallel. However, a group shuffled belief propagation (GSBP) algorithm may divide a plurality of the variable nodes VN into groups and may sequentially perform parallel decoding per group, by effectively converting an iteration or iterative operation into plural sub-iterations or sub-iterative operations. Therefore, a GSBP decoder may propagate newly updated messages obtained in sub-iterations to subsequent sub-iterations in neighboring groups, for achieving faster convergence with reduced parallel decoding complexity. The GSBP algorithm may generalize a column-layered based BP decoder by allowing a group to contain more than one variable node VN. Similar to the BP algorithm, group shuffled and column-layered based decoding may be applied to the BF algorithm. Hereinafter, according to an embodiment, an apparatus or a method for reducing complexity by performing decoding processes based on different BF algorithms in parallel will be described.

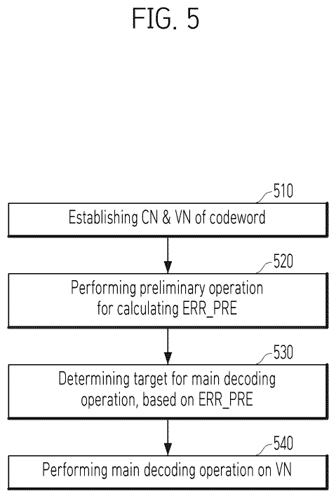

FIG. 5 describes an LDPC decoding method according to another embodiment of the present disclosure.

Referring to FIG. 5, the LDPC decoding method may include an establishing operation 510 of a plurality of the variable nodes VN and check nodes CN for a codeword. Each of the variable nodes VN may include a plurality of unit variable nodes, and each of the check nodes CN may include a plurality of unit check nodes.

The LDPC decoding method may include a preliminary operation 520 for estimating (or calculating) predictive error information ERR_PRE. The predictive error information ERR_PRE may include a presence of errors, the number of errors and a location of errors. The number of errors may indicate the number and amount of bit flipping operations that must be performed on the variable node VN to correct errors in the codeword. That is, the number of errors may include the number of flipped bits in the variable node VN. The LDPC decoder may determine flipping necessity and flipping frequency regarding variable nodes VN based on check nodes CN according to the predictive error information ERR_PRE.

The LDPC decoding method may perform a determining operation 530 of the variable node VN that is a target of the bit flipping operation (i.e., a target for a main decoding operation) by referring to the predictive error information ERR_PRE. The LDPC decoding method may include a determining operation of the amount of bit flipping operation to be performed on the determined variable node VN. The bit flipping operation may include iterative operations and/or sub-iterative operations. In the present disclosure, the bit flipping operation will be referred to as a main decoding operation.

The LDPC decoding method may include the main decoding operation 540 for correcting errors included in the determined variable node VN.

The preliminary operation for calculating the predictive error information ERR_PRE and the main decoding operation for error correction may be performed by different types of flipping function operations. For example, the preliminary operation may include a pre-flipping function operation, and the main decoding operation may include a main flipping operation.

According to an embodiment, the controller 130 may perform the main decoding operation using a two-bit weighted bit flipping algorithm in which each of the plurality of the variable nodes VN includes a value bit and a state bit. In addition, the controller 130 may perform the preliminary operation using a column-layered group shuffled bit flipping algorithm in units of columns each configured by circulant permutation matrixes (CPMs).

The LDPC decoding method described in FIG. 5 would be distinguished from a decoding method for performing a same bit flipping algorithm in parallel to reduce implementation complexity. The LDPC decoding method described in FIG. 5 may change, adjust, or limit iterations and/or sub-iterations in a main decoding algorithm based on a result of performing a pre-decoding algorithm as a spearhead decoding operation. The main decoding algorithm may be different and distinguished from the pre-decoding algorithm performed as the spearhead decoding operation. Through this procedure, complexity of a decoding operation required to search for and/or correct an error in the codeword (N, K) LDPC_CODE may be reduced. Accordingly, complexity regarding a decoder implemented in the controller 130 could be reduced.

With the introduction of high-speed applications such as memory device 150, there is a need for fast and low complexity error control coding. A message passing algorithm using an LDPC code for a decoding process, such as the sum-product algorithm (SPA), might have good error performance in a code where a degree of a variable node VN is 4 or less. However, complexity of the algorithm may be high, or a decoding speed may be restricted. For 3-left-regular LDPC codes that allow lower complexity implementations, a message passing algorithm (or other types of decoding algorithms) may generally have a high error floor. Among existing decoding algorithms for LDPC codes of binary symmetric channels (BSCs), the bit flipping algorithm may be the fastest and least complex, so it could be suitable for high-speed applications and fault-tolerant memory applications. In the bit flipping algorithm, a check node CN task may include a modulo-two additions operation (Bit exclusive OR (XOR) operation), and a variable node VN task may include a simple comparison operation. Further, a decoding speed might not depend on a left/right degree of the code. The bit flipping algorithm may reduce computational complexity when there is some soft information. To this end, an additional bit may be used in the bit flipping algorithm to indicate a strength of the variable node VN (e.g., reliability regarding a value of the variable node VN). For example, when given a combination of satisfied and dissatisfied check nodes CN, the bit-flip algorithm may reduce the strength of the variable nodes VN before flipping them. To indicate reliability, an additional bit may also be used in the check node CN. According to an embodiment, a strength of the variable node VN in an LDPC decoding is its ability to efficiently update and propagate information between the variable nodes VN and the check nodes CN. The variable node VN may update the probability distribution of each bit based on the messages it receives from the check nodes CN, and then send updated messages back to the check nodes CN. This may allow for iterative decoding algorithms to converge quickly and accurately to the correct codeword.

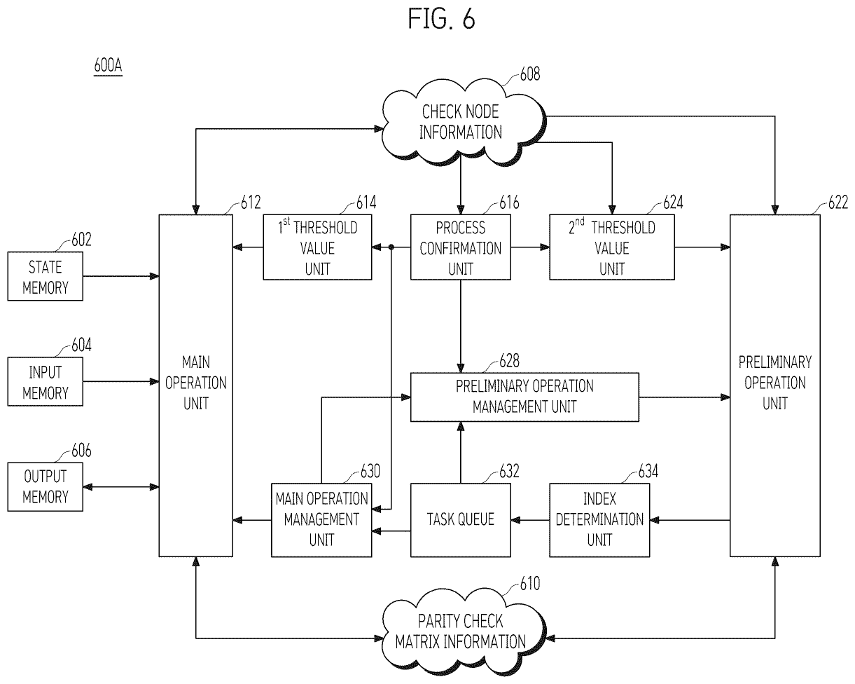

FIG. 6 describes an LDPC decoder 600A according to another embodiment of the present disclosure.

Referring to FIG. 6, the LDPC decoder 600A may include an input memory 604 for storing input codewords from a memory device, an output memory 606 for storing decoding results, and a state memory 602 for storing state information.

The LDPC decoder 600A may include a main operation unit 612. The main operation unit 612 may receive a codeword from the input memory 604 and perform an iterative operation on the codeword. According to an embodiment, the main operation unit 612 may include either two separate processors which are used as a detector and a decoder respectively or a single processor used as both a detector and a decoder. The main operation unit 612 may include a control circuitry configured to repeatedly correct and/or detect an error included in the codeword.

The main operation unit 612 may perform an iterative operation for a decoding process based on check node information 608 and parity check matrix information 610. According to an embodiment, the iterative operation for the decoding process may be performed based on the LDPC code described in FIGS. 1 and 2. The LDPC decoding to generate a decoded message may be understood by referring to Equations 1 and 2 above described. The parity check matrix H included in the parity check matrix information 610 may be a low-density n×m matrix (e.g., 4×6 matrix in FIG. 2). In this case, ‘n’ may correspond to (N+K) bits, which is the length of the codeword (N, K) LDPC_CODE, where ‘m’ is the number of check nodes CN. The parity check matrix H does not necessarily have to be unique. The parity check matrix H may be selected or designed for computational convenience in order to reduce the number of errors generated by a decoding technique of the LDPC decoder 600. According to an embodiment, the check node information 608 may include information (e.g., a number) regarding a satisfied check node CN and an unsatisfied check node UCN.

An iterative decoding method used in the main operation unit 612 may handle the codeword by updating symbols, reliability data, or both based on one or more flipping functions. The flipping function may calculate a function value that is compared to a threshold to determine whether a symbol has been previously updated, flipped, or toggled based on a value of the reliability or strength and whether a symbol's check has been satisfied or not based on any suitable combination thereof.

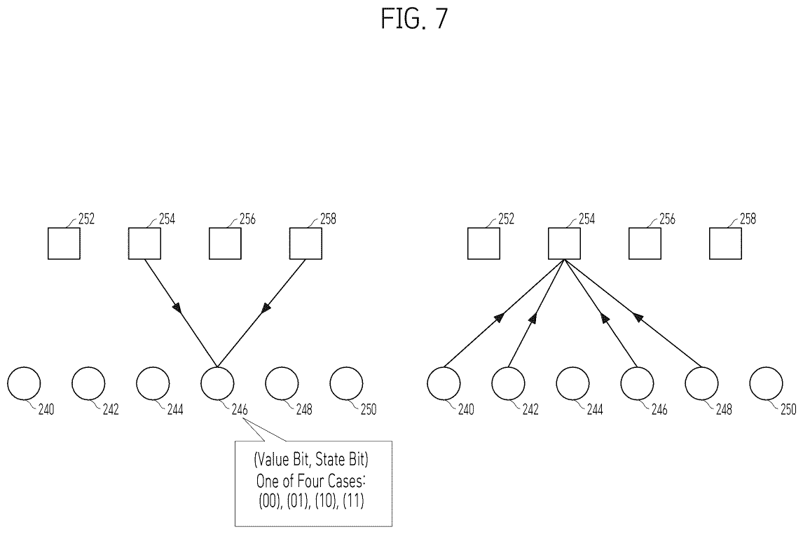

Information on the reference or the threshold value for the flipping function may be stored in a first threshold value unit 614. The main operation unit 612 may use information stored in the first threshold value unit 614 to perform an iterative operation. The main operation unit 612 may reduce a total number of decoding iterations required to reach convergence based on a hard-decision decoding input, a reliability input, and decoding results so far. A detailed operation of the main operation unit 612 will be described later, referring to FIGS. 7 to 10.

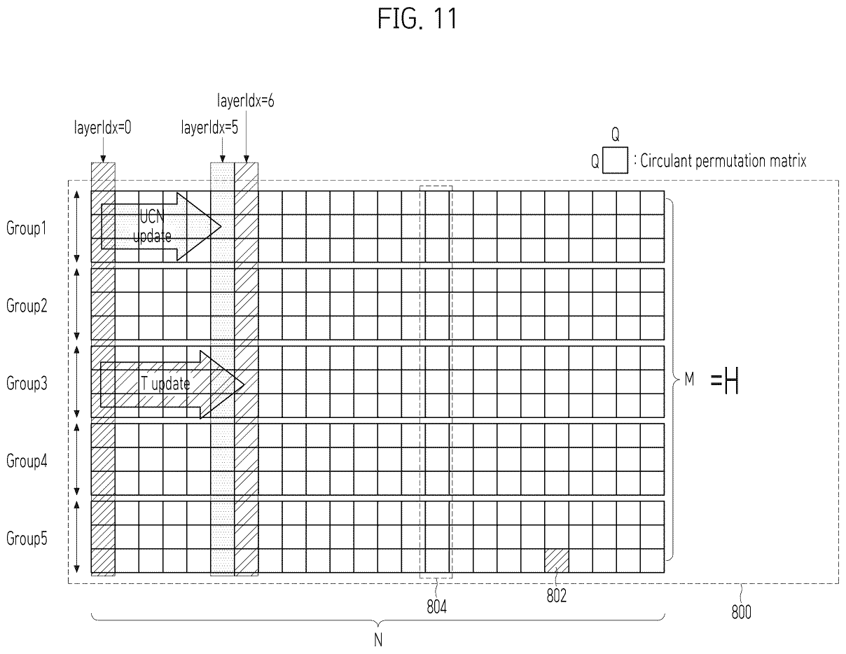

The LDPC decoder 600A may include a preliminary operation unit 622. Unlike the main operation unit 612, the preliminary operation unit 622 may independently check or estimate the predictive error information ERR_PRE regarding the plurality of the variable nodes VN based on the plurality of check nodes CN based on the predictive error information ERR_PRE. The preliminary operation unit 622 may refer to a second threshold value unit 624 in order to check the predictive error information ERR_PRE regarding the plurality of the variable nodes VN. The preliminary operation unit 622 may check or estimate whether or not bit flipping is performed based on an algorithm different from that used in the main operation unit 612, rather than performing a part of the iterative operation performed by the main operation unit 612 for a parallel processing. According to an embodiment, the main operation unit 612 and the preliminary operation unit 622 may use a QC-LDPC code using a QC parity check matrix. An operation of the preliminary operation unit 622 will be described later, referring to FIGS. 11 to 13.

According to an embodiment, the first threshold value unit 614 and the second threshold value unit 624 may have different threshold values. The threshold values may vary according to iterative operations performed by the main operation unit 612 and the preliminary operation unit 622. The first threshold value unit 614 or the second threshold value unit 624 may check iteration information (Iteration info.) or cycle information (Cycle info.) through a process confirmation unity 616.

Referring to FIG. 6, the LDPC decoder 600A may establish the plurality of the variable nodes VN and the plurality of check nodes CN from the codeword. In addition, the LDPC decoder 600A may include the preliminary operation unit 622 configured to perform a preliminary operation to check or estimate the necessity and frequency of bit flipping for the plurality of the variable nodes VN based on the plurality of check nodes CN, and the main operation unit 612 configured to perform only an iterative operation determined based on the necessity and frequency of bit flipping, which is a result output from the preliminary operation unit 622, to determine the plurality of the variable nodes VN.

According to an embodiment, the LDPC decoder 600A may further include a preliminary operation management unit 628 configured to determine a second iteration operation index for the preliminary operation to be performed by the preliminary operation unit 622.

In the present disclosure, ‘index’ may mean a column index. ‘Column’ may include a plurality of ‘unit cyclic permutation matrices’ arranged in the vertical direction of an LDPC submatrix. One unit cyclic permutation matrix (CPM) may be a square matrix composed of one unit variable node VN and one unit check node CN.

The preliminary operation unit 622 may perform a second iterative operation (e.g., iteration or sub-iteration) corresponding to the second iteration operation index determined by the preliminary operation management unit 628. For example, the preliminary operation unit 622 may check or estimate whether bit flipping is necessary for each variable node VN based on the plurality of check nodes CN, apart from the main decoding operation performed by the main operation unit 612. After receiving the second iteration operation index for the iterative operation from the preliminary operation management unit 628, the preliminary operation unit 622 may perform the iterative operation by referring to the value stored in the second threshold value unit 624 before the main operation unit 612 performs the corresponding iterative operation. Through this procedure, the LDPC decoder 600 may check whether bit flipping is necessary for correcting an error in the codeword through the preliminary operation performed in advance by the preliminary operation unit 622.

According to an embodiment, the LDPC decoder 600A may further include an index determination unit 634 configured to determine a first iterative operation index (e.g., iteration or sub-iteration index) for the main decoding operation based on the flipping necessity and the flipping frequency estimated by the preliminary operation unit 622, and a task queue 632 configured to store the first iterative operation index determined by the index determination unit 634. The main operation unit 612 may perform the main decoding operation including an iterative operation corresponding to the first iteration operation index stored in the task queue 632.

According to an embodiment, the index determination unit 634 may change or adjust the first iteration operation index and the second iteration operation index in response to the necessity and frequency of bit flipping regarding the plurality of the variable nodes VN. In this case, the task queue 632 may include a plurality of queues, each queue storing the first iteration operation index and the second iteration operation index respectively.

According to an embodiment, the preliminary operation management unit 628 may adjust or change the second iteration operation index in response to a number of the iterative operations (e.g., an amount of calculation) corresponding to the first iteration operation indexes stored in the task queue 632. If the number of the second iterative operations increases, a location and a probability regarding an error included in the codeword could be more specified. When information regarding the error is clearer, the number of main decoding operations performed by the main operation unit 612 could be reduced.

According to an embodiment, the LDPC decoder 600 may further include a main operation management unit 630 configured to control the main operation unit 612 for performing the main decoding operation including iterative operations corresponding to the first iteration operation index. Herein, the main operation management unit 630 may set or determine an iterative operation range of the main decoding operation, which is performed by the main operation unit 612, corresponding to whether or not the preliminary operation unit 622 operates.

FIG. 7 describes a first example of operations performed by the main operation unit 612 described in FIG. 6. Specifically, FIG. 7 is a diagram showing an example of a parity check matrix H of an LDPC code including 4 rows and 6 columns described in FIG. 2 and a Tanner graph thereof. The operation of the main operation unit 612 will be described with reference to FIGS. 1 to 7.

Referring to FIG. 2, the Tanner graph of an LDPC code encoded and decoded based on the parity check matrix H may include six variable nodes 240, 242, 244, 246, 248, 250 and four check nodes 252, 254, 256, 258.

Upon initialization of a decoding process of the LDPC decoder 600A, input states may be assigned to the variable nodes 240, 242, 244, 246, 248, 250 as described in FIG. 6. In this case, each variable node VN may include a value bit, which is hard-decision decoding information, and a state bit indicating reliability information. The value bit may refer to hard-decision decoding associated with a variable node VN, while the state bit may refer to reliability data associated with the corresponding variable node VN or its variable as data regarding variable reliability. Initially, the state bit may be input from the state memory 602 and the value bit may be input from the input memory 604. As decoding progresses, the state bits and the value bit could be stored in a buffer or a cache in the LDPC decoder 600A or in the output memory 606.

For example, every variable node VN is associated with a 2-bit input denoted by (y₀ y₁), where the value of bit y₀ represents the hard decision and the value of bit y₁ represents the reliability (e.g., either strong or weak, or either reliable or unreliable) of the hard decision. In the binary code, y₀ may take a value of 0 or 1, which represents the two possible hard-decision states of the decoded bit. Accordingly, y₁ may have a value of 0 or 1. For example, ‘0’ may indicate an unreliable decision and ‘1’ may indicate a reliable decision. That is, if two bits of ‘10’ are input to the variable node VN, it may be interpreted as an unreliable decision of ‘1.’ If ‘00’ is input to the variable node VN, it may be interpreted as an unreliable decision of ‘0.’ If ‘01’ is input to the variable node VN, it may be interpreted as a reliable decision of ‘0.’ If ‘10’ is input into the variable node VN, it is interpreted as an unreliable decision of ‘1.’ If ‘11’ is entered into the variable node VN, it may be interpreted as a reliable decision of ‘1.’

In FIG. 6, the hard-decision information and the reliability information are respectively stored in the state memory 602 and the input memory 604, which are different memories. The hard-decision information and the reliability information may also be stored in a single memory. Although only 1 bit is used to represent hard-decision information and only 1 bit is used to represent reliability of hard-decision information as an example, any number of bits may be used according to an embodiment. For example, the hard decision information may have more than one value for non-binary codes, and the reliability information may be conveyed through one or more bits or symbols as well.

After variable nodes 240, 242, 244, 246, 248, 250 are assigned, as shown in FIG. 2, variable node VN checking may be performed by the main operation unit 612 in the LDPC decoder 600A for a plurality of the variable node VN groups. The main operation unit 612 may use a flipping function, which is a processing rule, to determine whether to flip a variable node VN. An indication of determined condition may be stored in a syndrome memory such as the check nodes 252, 254, 256, 258. The parity check matrix H is used to identify which check nodes CN store an indication of the determined condition regarding the variable nodes VN.

Referring to FIGS. 2 and 7, each row of the parity check matrix H corresponds to one of the check nodes CN, and each column of the parity check matrix H corresponds to one of the variable nodes VN. In the case of a binary code, entries of the parity check matrix H are 0 or 1 as shown. A “neighboring” check node CN for a variable node VN is the check node CN that is connected to the variable node VN. Similarly, a “neighbor” variable node VN for a check node CN is the variable node VN that is connected to the check node CN. The parity check matrix H may provide an indication of the connection between the check node CN and the variable node VN. In particular, as shown in FIG. 7, variable nodes 240, 242, 246, 248 are neighbors of a check node 254, and check nodes 254, 258 are neighbors of a variable node VN 248. Also, each check node CN in the binary code has one of two states: ‘0’ if the check is satisfied; and ‘1’ if the check is not satisfied. For non-binary code, the entries of the parity check matrix are non-binary and each check node CN has one of two or more states. Each row of the parity check matrix H may form a coefficient of a parity check equation calculated in a non-binary domain.

According to an embodiment, each check node CN may be further associated with one or more bits of check node CN reliability data. For example, if most of the variable nodes VN associated with the check node CN have unreliable variable values, calculated check node CN values may become marked as unreliable. Reliability of the check node CN value may be expressed by a corresponding single bit of the check node CN reliability data. In some embodiments, more than one bit of check node CN reliability data may be stored in the output memory 606, as well as updated through the decoding process. In FIG. 6, the output memory 606 may be implemented separately from the input memory 604 but may be implemented as a single integrated memory according to an embodiment.

The main operation unit 612 may refer to the parity check matrix information 610 to identify at least one variable node VN related to a specific check node CN or a variable node VN to be checked by the specific check node CN.

For example, with respect to the check node 254, the main operation unit 612 may determine a check result of the variable nodes 240, 242, 246, 248 (i.e., the 1st, 2nd, 4th, and 5th variable nodes VN).

A value in the second row of the parity check matrix H may be a coefficient of the parity check equation and be multiplied by the corresponding value of each variable node VN. For example, the arrows in FIG. 7 indicate that retrieved values flow from the variable nodes 240, 242, 246, 248 to the check node 254, so that it could be considered that the check node 254 may be used to check the variable nodes 240, 242, 246, 248. The value of the variable node VN may be retrieved by the main operation unit 612 which may calculate the value on behalf of the check node 254 according to a processing rule.

In addition, the main operation unit 612 may read a check node information based on a given first iterative operation index (e.g., an iteration or sub-iteration index), and calculate a flipping function for the check node CN. After that, the main operation unit 612 may store an operation result in the output memory 606 or an internal buffer, update state information for the check node CN and update the check node information.

The main operation unit 612 may determine whether a condition given to the check node 254 is satisfied or unsatisfied according to the values received from the variable nodes 240, 242, 246, 248. An indication of whether the check node 254 is satisfied or unsatisfied (i.e., the check node CN's “syndrome value” or “check node CN value”) is stored in check node information 608, which stores the check node CN's syndrome value or indication. In addition, reliability of the syndrome value of the check node CN could be updated based on values and reliability of the associated variable nodes VN.

After syndrome values for the check nodes 252, 254, 256, 258 are stored in the check node information 608, the values of the variable nodes 240, 242, 244, 246, 248, 250 may be updated based on the reliability of the variable node VN and the values of the check nodes CN. The parity check matrix information 610 may be used again by the main operation unit 612 to determine which check node CN should be accessed for a particular variable node VN. Referring to FIGS. 2 and 7, the parity check matrix H may indicate that the check nodes 254, 258 (i.e., the second and fourth check nodes CN) should be referenced to update the variable node VN 246. The state of the variable node VN 246 may be updated based on the indication of the referenced check node CN.

According to an embodiment, the value of the variable node VN 246 may be determined based on whether it has been previously updated, toggled, or flipped. Check nodes CN and variable nodes VN may be updated iteratively until all check nodes CN are satisfied (i.e., an all-zero syndrome is achieved) or until the maximum number of iterations is reached. The output of the main operation unit 612 may be stored in the output memory 606 as a hard decision result or a decoded message at the end of the decoding process.

According to an embodiment, one example of binary variable node VN update based on the reliability of a single state bit is described. At the iteration j, the hard decision data or variable node value of the variable node VN i is denoted by y₀(i, j), while the reliability data of the variable node VN i is denoted by y₁(i, j). In a case of an iterative operation where j>1, relationship between the updated variable value y₀(i, j) and the previous variable value y₀(i, j−1) is as shown in Equation 3 below:

$${y}_{0} ( i , j ) = {y}_{0} ( i , j - 1 ) ⊕ {f}_{( 0 , j )} ( {y}_{0} ( i , j - 1 ) , {y}_{1} ( i , j - 1 ) , u ( i , j ) ) \qquad ( Equation 3 )$$

Herein, u(i, j) denotes the total number of unsatisfied check nodes associated with VN i at the iteration j, and f(0, j) represents a flipping function (FF) for the variable value, an output value of the FF being 0 or 1 at the iteration j. The FF f(0, j) could indicate whether the previous variable node value should be flipped. According to an embodiment, a value or a result of the FF f(0, j) for variable values may correspond to the number of unsatisfied check nodes UCN exceeding a predetermined threshold value. The FF f(0, j) for the variable value may correspond to a pattern of unsatisfied check nodes UCN. The FF f(0, j) for variable value may vary according to the iterative operation j.

Dependence of the FF f(0, j) for the variable values on an input of the FF f(0, j) may change during iterations performed between initialization and convergence of the decoding process. For example, during the initialization of the decoding process, variable nodes VN might be updated only if a number of relevant check nodes CN are unsatisfied. According to an embodiment, the FF may be changed so that a variable node VN is updated if at least one of the relevant check nodes CN is unsatisfied after several iterations are performed based on a threshold value, a vector, iterative operation information, and a syndrome weight. According to an embodiment, an XOR operation may be performed between an output value of the FF f(0, j) for the variable value and the last variable node value to generate an updated variable node value y₀(i, j). According to another embodiment, the FF f(0, j) for the variable value may directly generate the updated variable node value y₀(i, j).

According to an embodiment, reliability information for variable nodes VN may be updated. In this case, the relationship between the updated reliability data for variable node y₁(i, j) and the previous value for variable node y₁(i, j−1) may be expressed as Equation 4 below:

$${y}_{1} ( i , j ) = {y}_{1} ( i , j - 1 ) ⊕ {f}_{( 1 , j )} ( {y}_{0} ( i , j - 1 ) , {y}_{1} ( i , j - 1 ) , u ( i , j ) ) \qquad ( Equation 4 )$$

Herein, f(1, j) is a FF for variable node reliability data and indicates whether the previous variable node reliability data should be toggled or flipped. Similar to the FF of the variable value f(0, j), the FF of the variable node reliability data may depend on the number of iterations already performed or directly generate updated variable node reliability data y₁(i, j).

According to an embodiment, in a case of a symmetric channel having a symmetric input, probability of detecting ‘0’ in the main operation unit 612 may be equal to probability of detecting ‘1.’ In this case, f(0, j) and f(1, j), which are FFs of variable value and variable node reliability data, may be independent of the variable value input y₀(i, j). Therefore, the FFs determined by Equations 3 and 4 may be simplified to Equations 5 and 6 below:

$${y}_{0} ( i , j ) = {y}_{0} ( i , j - 1 ) ⊕ {f}_{( 0 , j )} ( {y}_{1} ( i , j - 1 ) , u ( i , j ) ) \qquad ( Equation 5 )$$

$${y}_{1} ( i , j ) = {y}_{1} ( i , j - 1 ) ⊕ {f}_{( 1 , j )} ( {y}_{1} ( i , j - 1 ) , u ( i , j ) ) \qquad ( Equation 6 )$$

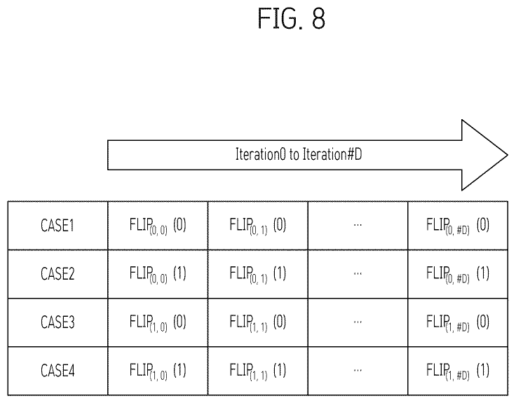

In iteration j, the number of unsatisfied check nodes u(i, j) associated with variable node i may have values from 0 to #D. Here, #D denotes the degree of the variable node i and corresponds to the column weight of the parity check matrix (H) in the LDPC code. Therefore, the second input to f(0, j), f(1, j), which are the FFs of variable value and variable node reliability data, may have a range from 0 to #D in Equations 5 and 6. According to an embodiment, the FFs f(0, j), f(1, j), which are two bit-flip processing rules, may be implemented as a table as shown in FIG. 8.

FIG. 8 describes a second example of operations performed by the main operation unit 612 described in FIG. 6. Specifically, FIG. 8 describes the FFs for four cases described in FIGS. 6 to 7. As described in FIG. 7, a variable node VN may have one of four cases: ‘00’, ‘01’, ‘10’, and ‘11’. Also, the FFs f_{(0, j)}, f_{(1, j)} may vary according to iterative operations.

Referring to FIG. 8, the variable value FF f_{(0, j)} will be determined from FLIP (0, 0) to FLIP_{(0, #D)}. The variable reliability data FF f_{(1, j)} may be determined from FLIP_{(1, 0)} to FLIP_{(1, #D)}.

In a first case CASE1, f₀(0) or FLIP₀(0), which is the variable value FF in a case of low reliability ‘0’, may be set from FLIP (0, 0) to FLIP_{(0, #D)}. In a second case CASE2, the variable value FF f₀ (1) or FLIP₀(1) may be set from FLIP_{(0, 0)} to FLIP_{(0, #D)} in a case of high reliability ‘1’. A third case CASE3 may be set for the variable reliability data FF f₁(0) or FLIP₁(0) from FLIP (1, 0) to FLIP_{(1, #D)} in the case of low reliability ‘0’. A fourth case CASE4 may be set for the variable reliability data FF f₁(1) or FLIP₁(1) from FLIP (1, 0) to FLIP_{(1, #D)} in the case of high reliability ‘1’.

According to an embodiment, a substantially same FF FLIP_{(0, x)} may be set for the first case CASE1 and the second case CASE2, and a substantially same FF FLIP_{(1, x)} may be set for the third case CASE3 and the fourth case CASE4.

According to an embodiment, the FF set in FIG. 8 may be stored in the first threshold value unit 614 described in FIG. 6. The main operation unit 612 may determine whether to flip the variable node VN based on a threshold value stored in the first threshold value unit 614. For example, the FF may be selected in a real time depending on whether the variable node i of the current iterative operation j (e.g., j is one of 0 to #D) is reliable. For example, when the variable node VN is currently unreliable ‘0’ and FLIP_{(0, j)}(0, u(i, j)), which is the FF of the variable value at the current iterative operation j, is 1, the main operation unit 612 may flip a hard decision value or a variable value connected to the corresponding node. When the variable node VN is currently unreliable ‘0’ and FLIP_{(1, j)}(0, u(i, j)), which is the FF of the variable reliability data in the current iterative operation j, is 1, the main operation unit 612 may flip reliability data of the corresponding node. When the variable node VN is currently reliable ‘1’ and FLIP_{(0, j)} (1, u(i, j)), which is the FF of the variable value in the current iterative operation j, is 1, the main operation unit 612 may flip the variable value related to the corresponding node. When the variable node VN is currently reliable ‘1’ and FLIP_{(1, j)}(1, u(i, j)), which is the FF of the variable node reliability data in the current iterative operation j, is 1, the main operation unit 612 may flip reliability data of the corresponding node.

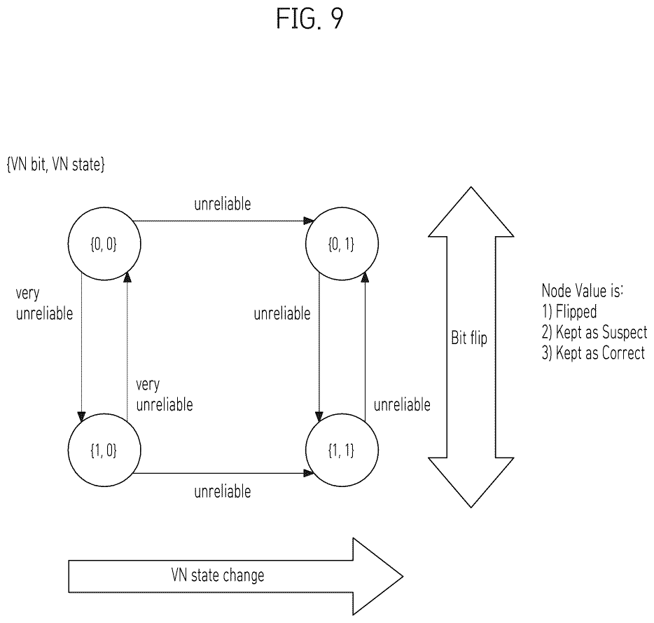

FIG. 9 describes a third example of operations performed by the main operation unit described in FIG. 6.

Specifically, when the variable node VN includes a value bit (variable node bit), which is hard-decision decoding information, and a state bit (variable node state) indicating reliability data, FIG. 9 describes change, flipping, or toggle regarding the value bit or the state bit.

The main operation unit 612 in the LDPC decoder 600A may change value bits of the variable nodes 240, 242, 244, 246, 248, 250 from ‘0’ to ‘1’ (state movement from top to bottom) or from ‘1’ to ‘0’ (moving state from bottom to top) in four cases. In addition, the main operation unit 612 may change state bits of the variable nodes 240, 242, 244, 246, 248, 250 from ‘0’ to ‘1’ (state movement from left to right) and from ‘1’ to ‘0’ (state movement from right to left) in the four cases.

For example, in order to determine whether value bits are flipped, the main operation unit 612 may determine flipping based on Equation 7 below:

$${V}_{th} ( i , j ) = ( {N}_{UCN} ( i - 1 ) + {α}_{j} \times i ) \times {β}_{j} \qquad ( Equation 7 )$$

Here, Vₜₕ(i, j) is the j-th FF reference value in the i-th iterative operation, i is the current number of iterative operation, and j is an integer which is greater than or equal to 1 and less than or equal to N (i.e., the number of states that corresponding variable nodes VN may have). N_{UCN}(i−1) is the number of unsatisfied check nodes UCN in the (i−1)th iterative operation. αj and βj are weights applied to the j-th FF reference. Herein, the αj and the βj may be preset, so that the first FF reference value has the highest value and the Nth FF reference value has the lowest value. Referring to Equation 7, it may be seen that the FF reference value is variable according to the number of current iterative operations, a previous iterative operation result, and the number of states that the corresponding variable nodes VN may have. Furthermore, at the first iterative operation, N_{UCN}(0) may be the number of unsatisfied check nodes UCN (i.e., the number of check nodes CN having a value of ‘1’) among initialized check nodes CN included in the first data.

For example, the main operation unit 612 may determine whether to flip the state bit based on Equation 8 below:

$$R ( i , k ) = ( γ j \times {N}_{UCN} ( i - 1 , k ) + δ j \times {N}_{SCN} ( i - 1 , k ) ) \qquad ( Equation 8 )$$

Here, R(i, k) is the reliability data of the k-th VN in the i-th iterative operation, i is the number of current iterative operation, and N_{UCN}(i−1, k) is, at the (i−1)th iteration, the number of unsatisfied check nodes UCN connected to the k-th VN. N_{SCN}(i−1, k) is the number of satisfied check nodes CN connected to the k-th VN at the (i−1)th iterative operation. γj and δj are weights applied to the reliability data of the k-th VN. Referring to Equation 8, it may be seen that the reliability data of the k-th VN is changed according to the previous iterative operation result. Furthermore, in the first iterative operation, N_{UCN}(0, k) is the number of unsatisfied check nodes UCN (i.e., the number of check nodes CN having a value of ‘1’) connected to the k-th VN included in the first data, and N_{SCN}(0, k) is the number of satisfied check nodes CN (that is, the number of check nodes CN having a value of ‘0’) connected to the k-th VN included in the first data.

As described above, when the main operation unit 612 determines whether to flip the value bit and/or the state bit of the corresponding check node CN, the variable node VN becomes flipped, kept in a suspicious/unreliable state (kept as suspect), or kept as correct or reliable (kept as correct).

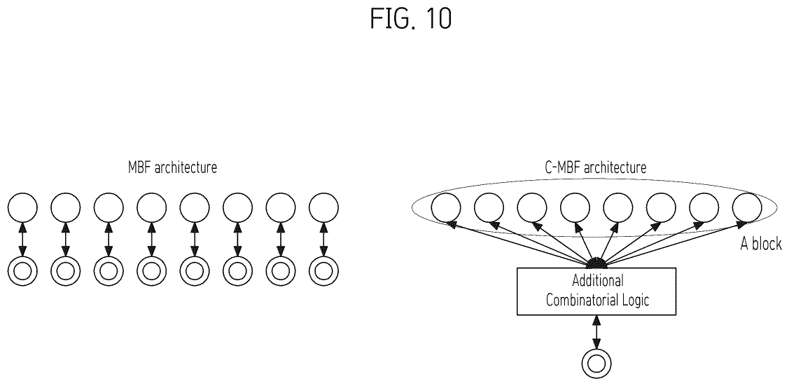

FIG. 10 describes a fourth example of operations performed by the main operation unit described in FIG. 6. Specifically, FIG. 10 describes two different types of the variable nodes VN in relation to the operation performed by the main operation unit 612.

As described above, in the main operation unit 612 in the LDPC decoder 600A, each of the variable nodes 240, 242, 244, 246, 248, 250 have four cases of ‘00,’ ‘01,’‘10,’ and ‘11.’ As an example, in a multistate bit-flipping (MBF) architecture, each of the plurality of the variable nodes 240, 242, 244, 246, 248, 250 has a value bit or a variable value (o) and a state bit or reliability data (@) which may be different. In another embodiment, in a combinatorial multistate bit-flipping (C-MBF) architecture, when each of the plurality of the variable nodes 240, 242, 244, 246, 248, 250 belonging to one group (e.g., A block), each of the plurality of the variable nodes 240, 242, 244, 246, 248, 250 may have a different value bit or variable value (o), but a same/common reliability data (@). To this end, the main operation unit 612 may include an additional combinatorial logic for handling common reliability data. The additional combinatorial logic may determine common reliability data for a corresponding group through a logical operation based on reliability data for the plurality of the variable nodes 240, 242, 244, 246, 248, 250 which belongs to a same group (e.g., A block).

According to an embodiment, a group may be set based on whether variable nodes VN are output via a same data path such as a channel or way, from a same memory die, or from a same memory block. If each group has a same reliability data, the main operation unit 612 may simplify an iterative operation for variable nodes VN.

FIG. 11 describes a first example of operations performed by the preliminary operation unit described in FIG. 6.

Referring to FIG. 11, a parity check matrix 800 may include M×N sub-matrices 802, each of which has a zero matrix or a cyclically shifted identity matrix of Q×Q dimension. According to an embodiment, a parity check matrix of a QC form may be used as the parity check matrix 800 for ease of implementation. The parity check matrix 800 may be characterized by having a parity check matrix including zero matrices or circulant permutation matrices (CPMs) of Q×Q dimension. In this case, the permutation matrix may include all entries of 0 or 1 and each row or column includes only one 1. A CPM may include a matrix obtained by circularly shifting each entry of an identity matrix to the right. Referring to FIG. 2, a structure of the LDPC code may be defined by a Tanner graph including check nodes CN, variable nodes VN, and edges connecting the check nodes CN and variable nodes VN.

The check nodes CN and the variable nodes VN constituting the Tanner graph may respectively correspond to rows and columns of the parity check matrix 800. Accordingly, the number of rows and columns of the parity check matrix 800 may coincide with the number of check nodes CN and variable nodes VN constituting the Tanner graph, respectively. When an entry of the parity check matrix 800 is 1, check nodes CN and variable nodes VN connected by edges on the Tanner graph may correspond to the row and column where the entry of ‘1’ is located, respectively.

According to an embodiment, the preliminary operation unit 622 in the LDPC decoder 600A may perform an LDPC decoding operation according to a bit flipping algorithm using a vertical-shuffled scheduling method. According to the vertical-shuffled scheduling method, the preliminary operation unit 622 may perform a variable node selection operation for selecting variable nodes VN corresponding to columns 804 constituting selected sub-matrices by selecting the selected sub-matrices sharing a same layer (layerIdx=0, layerIdx=5, layerIdx=6). The preliminary operation unit 622 may calculate a FF based on check nodes CN connected to the selected variable nodes VN. The preliminary operation unit 622 may refer to the values of the variable node VN and the check node CN already calculated by the main operation unit 612, but does not modify or update the values of the variable node VN and/or the check node CN. The preliminary operation unit 622 may determine in advance, e.g., estimate, whether to flip variable nodes VN based on the check node messages which are provided to the variable nodes VN receiving the check node messages. The preliminary operation unit 622 may perform the LDPC decoding process in a vertical-shuffled-scheduled manner by repeatedly performing the variable node selection operation, a check node update check operation, and a variable node VN update check operation until the LDPC decoding succeeds.

A BF algorithm for decoding LDPC codes may update all variable nodes VN and check nodes CN in parallel. According to an embodiment, the group shuffled (GS) BF algorithm may divide variable nodes VN into groups and serially perform decoding operations for each group, so that the decoding iterative operation (e.g., an iteration) may be effectively converted into several sub-iterative operations (e.g., sub-iterations). Therefore, the preliminary operation unit 622 performing group shuffle bit flipping (GS BF) decoding operation may transfer a newly updated message obtained from the sub-iteration operation to a neighboring group of the subsequent sub-iteration operation, while reducing parallel decoding complexity, thereby achieving faster convergence.

For example, the preliminary operation unit 622 may divide one iteration into sub-iterations in units of columns of sub-matrices 802 in the parity check matrix 800, and update bit flipping, an unsatisfied check node UCN, and a threshold value (T) whenever a sub-iterative operation is performed. According to an embodiment, the preliminary operation unit 622 may configure a sub-iteration operation in a unit corresponding to a cycle of the CPM. Through this configuration, computational complexity of the preliminary operation unit 622 may be reduced.

According to an embodiment, in one column 804 of the parity check matrix H shown in FIG. 11, the check nodes CN may be divided into different groups Group1, Group2, Group3, Group4, Group5. The number of non-zero CPMs that exists in a group may be limited to a maximum of 1 (i.e., the number of non-zero CPMs in each group is 0 or 1). Through this code, it is possible to reduce the complexity of the LDPC decoder 600 by arranging a single check node CN calculator for a CPM unit per group.

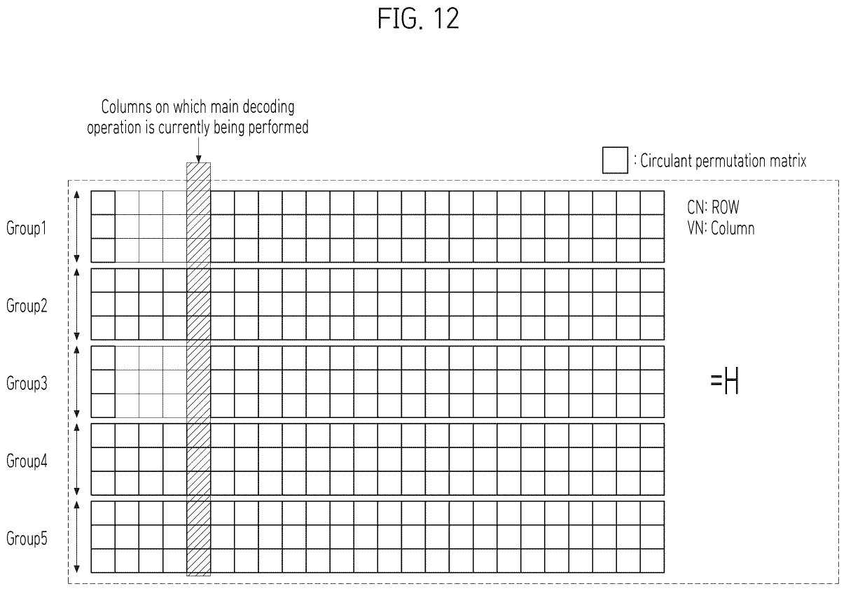

FIG. 12 describes a second example of operations performed by the preliminary operation unit described in FIG. 6.

Referring to FIG. 12, the parity check matrix H may have rows corresponding to the number of check nodes CN and columns corresponding to the number of the variable nodes VN.

Referring to FIGS. 6 and 12, the LDPC decoder 600A may include the main operation unit 612 and the preliminary operation unit 622. The main operation unit 612 may receive the codeword from the input memory 604 and perform an iterative operation. The preliminary operation unit 622 may perform a preliminary operation as a spearhead decoding operation compared to the main operation unit 612. The main operation unit 612 may limitedly perform an iterative operation for bit flipping based on a result of the spearhead decoding operation performed by the preliminary operation unit 622. For example, the main operation unit 612 may skip some of iterative operations based on the result output by the preliminary operation unit 622. The preliminary operation may include a pre-decoding operation.

When the codeword is initially received from the input memory 604, there is no result of the preliminary operation performed by the preliminary operation unit 622. Accordingly, the main operation unit 612 may perform an iterative operation corresponding to the first column based index (layerIdx=0). In order to avoid redundant iterative operations, the preliminary operation unit 622 may jump over or skip some of iterative operations from the first column based index (layerIdx=1) to a preset k-th based index (layerIdx=k), because the main operation unit 612 would perform the iterative operations from the first column based index (layerIdx=1) to a preset k-th based index (layerIdx=k). For example, referring to FIG. 12, when the main operation unit 612 performs an iterative operation corresponding to the first column based index (layerIdx=0), the preliminary operation unit 622 may perform an iterative operation corresponding to the 5th column (i.e., jump over iterative operations corresponding to the 1st to 4th columns).

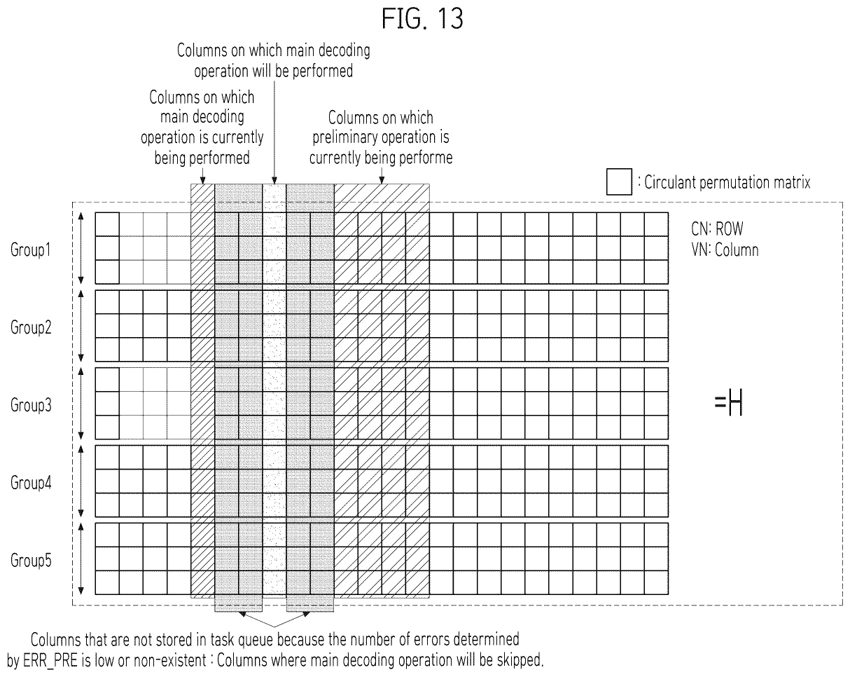

FIG. 13 describes a third example of operations performed by the preliminary operation unit described in FIG. 6.

Referring to FIGS. 6, 12, and 13, the operations are described based on the parity check matrix H in relation to iterative operations performed by the main operation unit 612 and the preliminary operation unit 622 included in the LDPC decoder 600A.

At a specific time point, the main operation unit 612 may perform a decoding operation by performing an iterative operation corresponding to the fifth column of the parity check matrix H, while the preliminary operation unit 622 performs a preliminary operation as a spearhead decoding operation by performing iterative operations corresponding to the 11th to 14th columns in the parity check matrix H. In addition, the preliminary operation unit 622 has already performed iterative operations corresponding to the 6th to 10th columns, so that information regarding iterative operations to be performed by the main operation unit 612 (i.e., a result of the spearhead decoding operation) may be stored in the task queue 632.

Referring to FIG. 13, the operation result of the preliminary operation unit 622 among the iterative operations corresponding to the 6th to 10th columns may show that some iterative operations corresponding to the 6th to 7th and 9th to 10th columns do not need to be performed by the main operation unit 612 except for the iterative operation corresponding to the 8th column. That is, the information regarding the iterative operation corresponding to the eighth column only may be stored in the task queue 632, and the main operation unit 612 may perform iterative operations corresponding to the only iterative operation index included in the task queue 632 (e.g., iterative operations corresponding to the 6th to 7th and 9th to 10th columns are omitted or skipped).

According to an embodiment, referring to FIGS. 12 and 13, the task queue 632 may include information regarding iterative operations corresponding to the first column in the parity check matrix H up to a preset k-th column which the preliminary operation unit 622 does not determine whether flipping is necessary. After the preset k-th column, the task queue 632 may include information regarding iterative operations to be performed by the main operation unit 612 in response to the operation result of the preliminary operation unit 622. Information on the iterative operation corresponding to the required column may be included. Through the task queue 632, the main operation unit 612 does not perform iterative operations corresponding to all columns in the parity check matrix H but may perform iterative operations corresponding to some columns in the parity check matrix H, which are stored in the task queue 632. Based on this procedure, the number of iterative operations performed by the LDPC decoder 600A may be reduced and the complexity of the LDPC decoder 600A may be improved.

As above described, complexity of a controller could be reduced by reducing an amount of computation consumed to check and correct errors included in data transmitted from a memory device of a memory system according to an embodiment of the present disclosure.

In addition, an LDPC decoder according to an embodiment of the present disclosure may include a plurality of bit flipping machines. Ranges of iterative operations based on parity check matrices performed by the plurality of bit flipping machines are different from each other. A number of iterative operations in the LDPC decoder (e.g., an amount of computation in the LDPC decoder) could be reduced based on different ranges of iterative operations, so that complexity of the LDPC decoder could be improved.

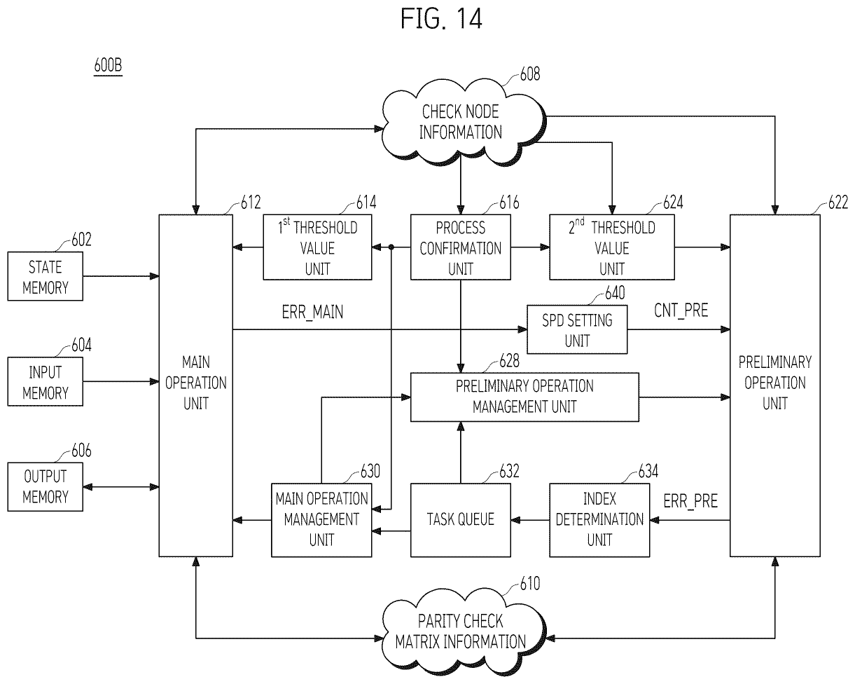

FIG. 14 describes an LDPC decoder 600B in accordance with another embodiment of the present disclosure.

In the description of FIG. 14, parts overlapping with FIG. 6 are omitted and differences with FIG. 6 are mainly described.

In the description of FIG. 14, an ‘index’ may mean an index of the variable node VN corresponding to the check node CN described with reference to FIGS. 1 to 13.

The LDPC decoder 600B may establish a plurality of check nodes CN for the codeword outputted from the memory device 150 (FIG. 1) and a plurality of the variable nodes VN corresponding to the plurality of check nodes CN.

The preliminary operation unit 622 may perform a preliminary operation for calculating predictive error information ERR_PRE on the plurality of the variable nodes VN. The preliminary operation may correspond to a preliminary operation described with reference to FIGS. 1 to 13, and may be a decoding operation performed as a spearhead of a main decoding operation in order to calculate the predictive error information ERR_PRE.

The predictive error information ERR_PRE may include at least one of the presence or absence of an error included in each of the plurality of the variable nodes VN, the number of errors, and the locations of errors. The preliminary operation unit 622 may include a plurality of unit preliminary operation units.

The index determination unit 634 may calculate an index (for example, iteration index/sub-iteration index), on which a main decoding operation is to be performed, based on the predictive error information ERR_PRE calculated by the preliminary operation unit 622. The main decoding operation may correspond to the main decoding operation described with reference to FIGS. 1 to 13 and may be a decoding operation for error correction.

The index determination unit 634 may store, in the task queue 632, only variable nodes VN on which the main decoding operation needs to be performed based on the predictive error information ERR_PRE. Through this, the main operation unit 612 may perform the main decoding operation only on variable nodes VN determined by the index determination unit 634, rather than on all variable nodes VN in the parity check matrix H. Accordingly, the LDPC decoder 600B in accordance with an embodiment of the present disclosure may reduce the number of iterations and improve the complexity of the LDPC decoder 600B.

The main operation management unit 630 may output indexes stored in the task queue 632 and the predictive error information ERR_PRE corresponding to the indexes to the main operation unit 612.

The main operation unit 612 may perform main decoding operations by referring to the predictive error information ERR_PRE received from the main operation management unit 630. The main decoding operation may include a bit flipping operation for error correction. The main operation unit 612 may store, in the output memory 606, a codeword corresponding to the variable node VN subjected to the main decoding operation and main error information ERR_MAIN.

The main error information ERR_MAIN may include the number nUSC of unsatisfied check nodes accumulated until error correction is completed, the number nITR of iterations of the main decoding operation performed until error correction is completed, the number nUECC of uncorrectable errors, and the like during the main decoding operation process. It may be determined that an error rate is high as the value of the main error information ERR_MAIN is large.

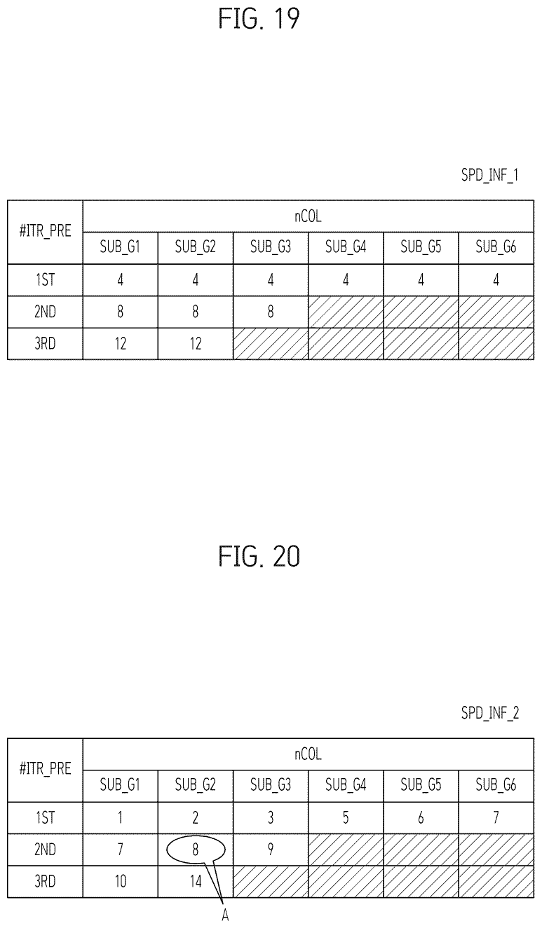

Before the preliminary operation is performed, an SPD setting unit 640 may set a preliminary operation speed SPD indicating the execution speed of the preliminary operation according to the progress rate of the preliminary operation. The set preliminary operation speed SPD may be recorded in the memory 144 (FIG. 1). The preliminary operation speed SPD may be structured like preliminary operation speed information SPD_INF1 and SPD_INF2 illustrated in FIGS. 19 and 20.

The SPD setting unit 640 may set the preliminary operation speed SPD to be lower as the progress rate of the preliminary operation approaches an “early stage”, and set the preliminary operation speed SPD to be higher as the progress rate of the preliminary operation approaches a “late stage”. The SPD setting unit 640 may set the preliminary operation speed SPD to be proportional to the progress rate of the preliminary operation. The progress rate of the preliminary operation may be proportional to the number of iterations of the preliminary operation and the execution order of a plurality of sub-preliminary operations included in the preliminary operation.

The preliminary operation speed SPD may mean the number nVN of the variable nodes on which the preliminary operation is performed during a unit time tCYCLE. That is, the SPD setting unit 640 may differently set the number nVN of the variable nodes, on which the preliminary operation is performed during the unit time tCYCLE, according to the progress rate of preliminary operation, so that as a result, the preliminary operation speed SPD may be varied. This means that the number of unit preliminary operation units driven during the unit time tCYCLE is set differently.

For example, the SPD setting unit 640 may set the number nVN of the variable nodes on which the preliminary operation is performed during the unit time tCYCLE to be small as the progress rate of the preliminary operations approaches an “early stage”, and may set the number nVN of the variable nodes on which the preliminary operation is performed during the unit time tCYCLE to be large as the progress rate of the preliminary operations approaches a “late stage”. That is, the SPD setting unit 640 may set the number nVN of the variable nodes on which the preliminary operation is performed during the unit time tCYCLE to be proportional to the progress rate of the preliminary operation.

The SPD setting unit 640 may re-set the already set preliminary operation speed SPD according to an error rate based on the main error information ERR_MAIN. Since the error rate is determined based on the main error information ERR_MAIN, the following description is made based on that the error rate and the main error information ERR_MAIN have the same meaning. The re-setting of the already set preliminary operation speed SPD may include changing the number nVN of the variable nodes on which the preliminary operation is performed during the unit time tCYCLE.

As the progress rate of the preliminary operation approaches an “early stage” or the error rate ERR_MAIN is higher, the SPD setting unit 640 may set the number nVN of the variable nodes on which the preliminary operation is performed during the unit time tCYCLE to be smaller. As the progress rate of the preliminary operation approaches a “late stage” or the error rate ERR_MAIN is lower, the SPD setting unit 640 may set the number nVN of the variable nodes on which the preliminary operation is performed during the unit time tCYCLE to be higher.

The SPD setting unit 640 may adjust the number nVN of the variable nodes on which the preliminary operation is performed during the unit time tCYCLE, according to at least one of the progress rate of the preliminary operation and the error rate ERR_MAIN.

Depending on the embodiment, the SPD setting unit 640 may determine to re-set the preliminary operation speed SPD when the determined progress rate of the preliminary operation is a late stage.

When the preliminary operation is started, the SPD setting unit 640 may increase the value of a pointer PT_PRE each time the preliminary operation is performed and record the increased value in the memory 144. The SPD setting unit 640 may determine the progress rate of the preliminary operation currently being performed in real time based on the pointer PT_PRE recorded in the memory 144.

The SPD setting unit 640 may output, to the preliminary operation unit 622, a drive control signal CNT_PRE for selectively driving the unit preliminary operation units included in the preliminary operation unit 622.

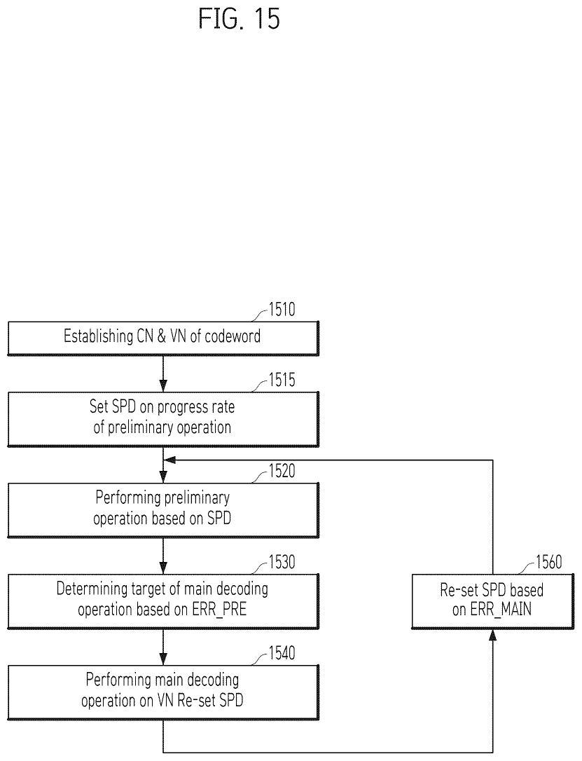

FIG. 15 describes the operation of the LDPC decoder 600B described with reference to FIG. 14. In the description of FIG. 15, parts that overlap with FIG. 5 are omitted and differences with FIG. 5 are mainly described.

As illustrated in FIG. 15, the LDPC decoder 600B may set (or establish) a plurality of check nodes CN for the codeword and a plurality of the variable nodes VN corresponding to the plurality of check nodes CN (1510). Each of the variable nodes VN may include a plurality of unit variable nodes, and each of the check nodes CN may include a plurality of unit check nodes.

Before a preliminary operation is performed, the LDPC decoder 600B may set a preliminary operation speed SPD based on the progress rate of the preliminary operation scheduled to be performed (1515).

Based on the set preliminary operation speed SPD, the LDPC decoder 600B may perform a preliminary operation for calculating predictive error information ERR_PRE for each of the plurality of the variable nodes VN (1520).

Based on the determined progress rate of the preliminary operation and the preliminary operation speed SPD, the LDPC decoder 600B may adjust the preliminary operation speed SPD.

The LDPC decoder 600B may determine a variable node VN, on which a main decoding operation is to be performed, (i.e., a target of the main decoding operation), by referring to the predictive error information ERR_PRE (1530). The LDPC decoder 600B may perform a main decoding operation for error correction on each of the variable nodes VN determined in 1530 among the variable nodes VN on which the preliminary operation has been performed (1540).

The LDPC decoder 600B may re-set the preliminary operation speed SPD according to an error rate ERR_MAIN calculated in the main decoding operation process (1560).

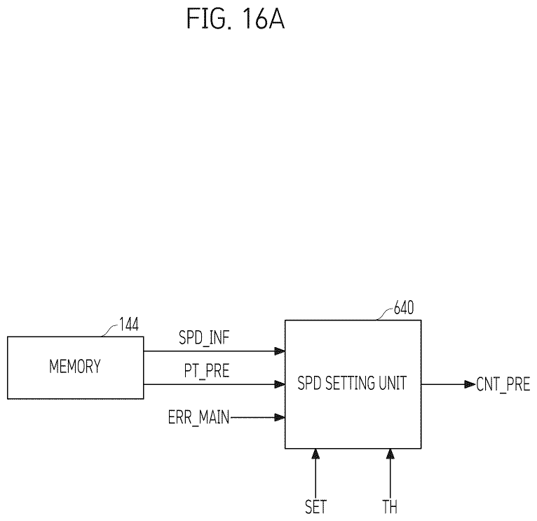

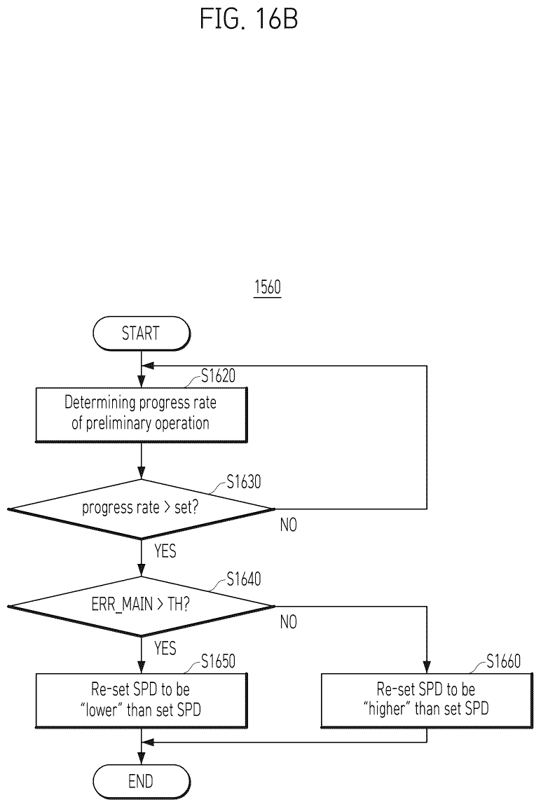

The operation of the SPD setting unit 640 described with reference to FIG. 14 is described with reference to FIGS. 16A and 16B in detail below. FIG. 16A illustrates the structure of the SPD setting unit 640. FIG. 16B describes a method for re-determining the preliminary operation speed SPD.

Referring to FIGS. 16A and 16B, the SPD setting unit 640 may determine the progress rate of the preliminary operation currently being performed in real time by using the pointer PT_PRE stored in the memory 144 (FIG. 1) (S1620). The SPD setting unit 640 may determine that the larger the value of the pointer PT_PRE, the higher the progress rate of the preliminary operation.

The SPD setting unit 640 may control the preliminary operation unit 622 based on the determined progress rate of the preliminary operation and preliminary operation speed information SPD_INF stored in the memory 144 (S1620). To this end, the SPD setting unit 640 may output, to the preliminary operation unit 622, the drive control signal CNT_PRE for selectively driving the unit preliminary operation units included in the preliminary operation unit 622.

The SPD setting unit 640 may compare the progress rate of the preliminary operation with a specific value SET stored in the memory 144 (S1630). This is to determine whether the progress rate of the preliminary operation is a “late stage” or not. In some embodiments, the specific value SET may include a value of 50% or more.

When it is determined that the progress rate of the preliminary operation does not exceed the specific value SET (S1630, NO), the SPD setting unit 640 may return to the operation of S1620 and perform subsequent operations.

When it is determined that the progress rate of the preliminary operation exceeds the specific value SET (S1630, YES), the SPD setting unit 640 may compare the error rate ERR_MAIN with a threshold value TH stored in the memory 144 (S1640). The threshold value TH may be stored in a first threshold value unit 614.

When it is determined that the error rate ERR_MAIN does not exceed the threshold value TH (S1640, NO), the SPD setting unit 640 may re-set the preliminary operation speed SPD of a preliminary operation to be subsequently performed to be higher than a set speed (S1660). The set speed means a speed corresponding to the preliminary operation speed information SPD_INF.

However, when it is determined that the error rate ERR_MAIN exceeds the threshold value TH (S1640, YES), the SPD setting unit 640 may re-set the preliminary operation speed SPD of the preliminary operation to be subsequently performed to be lower than the set speed (S1650). In such a case, the re-set preliminary operation speed SPD may be lower than or equal to the speed of a preliminary operation recently performed.

In this way, the SPD setting unit 640 in accordance with an embodiment of the present disclosure may re-set the preliminary operation speed SPD, which has already been set based on the progress rate of a preliminary operation, in real time according to the error rate ERR_MAIN.

Depending on the embodiment, the SPD setting unit 640 may not set the preliminary operation speed SPD in advance before performing a preliminary operation. In such a case, the SPD setting unit 640 may control the preliminary operation speed SPD to be proportional to the progress rate of the preliminary operation by increasing a preliminary operation speed SPD of a preliminary operation scheduled to be performed compared to the speed of a preliminary operation recently performed.

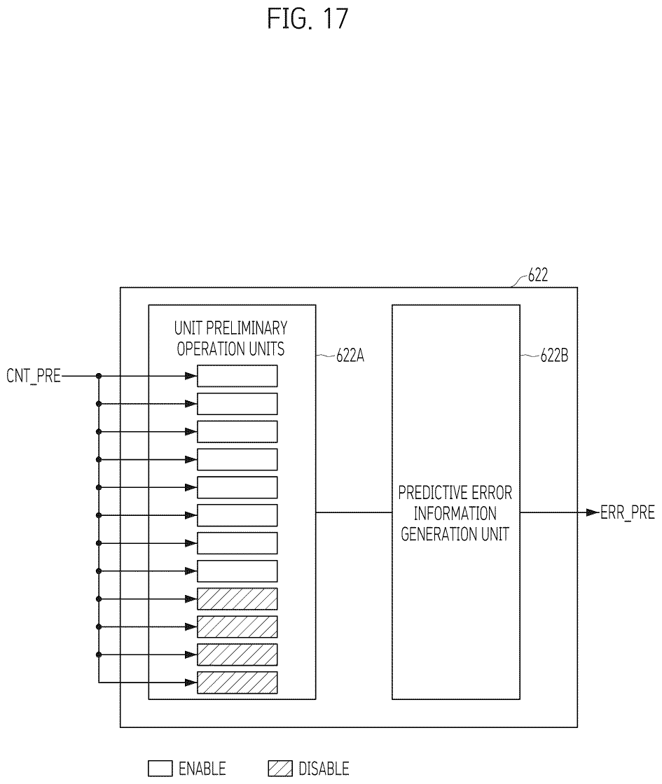

FIG. 17 illustrates the structure of the preliminary operation unit 622 described with reference to FIG. 14.

Referring to FIG. 17, the preliminary operation unit 622 may include a plurality of unit preliminary operation units 622A and a predictive error information generation unit 622B.

The unit preliminary operation units 622A may be selectively enabled according to the drive control signal CNT_PRE inputted from the SPD setting unit 640.

As illustrated in FIG. 17, when the progress rate of the preliminary operation approaches an “early stage” or the error rate ERR_MAIN is high, four of 12 unit preliminary operation units 622A may be enabled and eight of them may be disabled. Accordingly, the preliminary operation unit 622 may perform a preliminary operation on four variable nodes VN per unit time tCYCLE.

When the progress rate of the preliminary operation approaches a “late stage” or the error rate ERR_MAIN is low, the 12 unit preliminary operation units 622A may all be enabled. Accordingly, the preliminary operation unit 622 may perform a preliminary operation on 12 variable nodes VN per unit time tCYCLE.

In this way, the preliminary operation unit 622 may adjust the preliminary operation speed SPD by adjusting the number of the plurality of unit preliminary operation units 622A driven during the unit time tCYCLE.

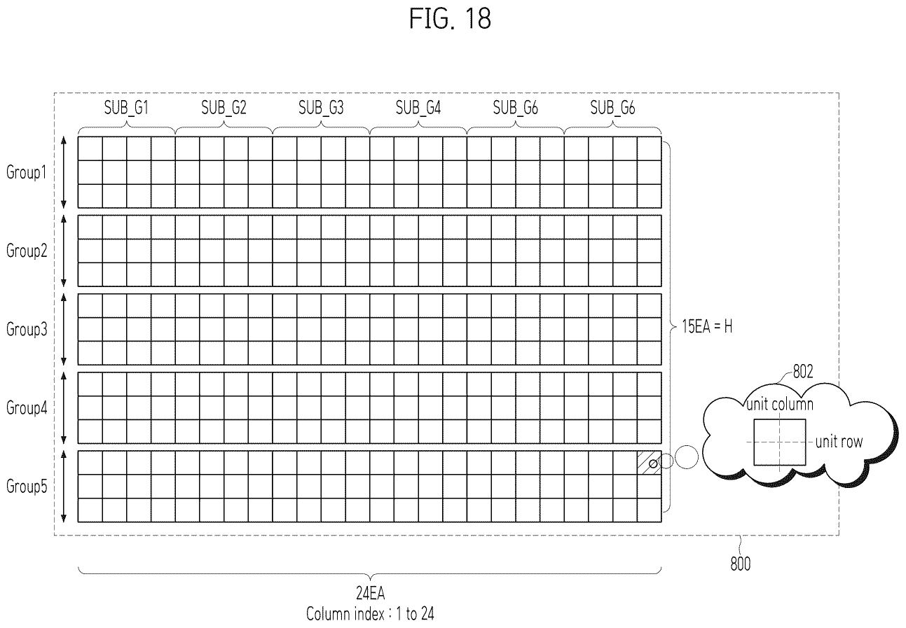

A preliminary operation performed on columns is described below with reference to FIGS. 18 to 21. Columns described with reference to FIGS. 18 to 21 may correspond to the variable nodes VN described with reference to FIGS. 14 to 17.

FIG. 18 illustrates a parity check matrix 800 including a parity check matrix H constituted by 15×24 sub-matrices 802.

The structure of the LDPC code corresponding to data of the present disclosure may be defined by a parity check matrix H and a Tanner graph. The parity check matrix H may be structured with a plurality of columns and a plurality of rows. In such a case, the intersection of the column and the row may be referred to as a sub-matrix 802. The sub-matrix 802 may be structured with one unit column and one unit row.

The Tanner graph may be constituted by a plurality of the variable nodes VN, a plurality of check nodes CN, and lines (edges) connecting the variable nodes VN and the check nodes CN. One variable node VN may include a plurality of unit variable nodes, and one check node CN may include a plurality of unit check nodes.

The columns and the rows of the parity check matrix H may correspond to the variable nodes VN and the check nodes CN of the Tanner graph, respectively. The unit column and the unit row of the parity check matrix H may correspond to the unit variable node VN and the unit check node CN of the Tanner graph, respectively. For example, a second column and a third row of the parity check matrix H may correspond to a second variable node VN and a third check node CN of the Tanner graph, respectively.

The fact that the value of the sub-matrix 802 corresponding to the intersection of the second column and the third row of the parity check matrix H is ‘1’ may mean that the second variable node VN and the third check node CN of the Tanner graph are connected by lines (edges).

In the Tanner graph, the degree of the variable node VN and the check node CN means the number of lines (edges) connected to each node. The number of lines (edges) may be equal to the number of entries each having a value of ‘1’ among entries included in a column or row corresponding to a node in the parity check matrix H of the LDPC code.

In the description of FIG. 18, an ‘index’ means an identification number of the column. For example, a column index ‘3’ may refer to a third column from the left in the parity check matrix H. The column may correspond to the variable node VN described with reference to FIGS. 14 to 17.

The controller 130 of FIG. 1 may perform a preliminary operation according to a bit flipping algorithm by using a vertical shuffled scheduling method. That is, the controller 130 may select a column by selecting sub-matrices 804 with the same ‘index’. The ‘column’ may include a plurality of ‘sub-matrices 802’ arranged vertically in the parity check matrix H.

A one-time preliminary operation performed on a plurality of columns may include a plurality of sub-preliminary operations. Accordingly, the controller 130 may complete a one-time preliminary operation by performing a plurality of sub-preliminary operations on different columns.

In order to perform a sub-preliminary operation, the controller 130 may generate a plurality of sub pre-decoding groups by grouping a plurality of columns included in the parity check matrix H. The sub pre-decoding group may be an execution unit of a sub-preliminary operation. The controller 130 may set execution times T_PRE of the plurality of sub-preliminary operations to be the same as a unit time (for example, 1 tCYCLE). The number of columns included in the sub pre-decoding group may be the number of columns on which a preliminary operation is performed per unit time tCYCLE.

The controller 130 may adjust the preliminary operation speed SPD by varying the number nCOL of a plurality of columns on which the preliminary operation is to be performed during the unit time tCYCLE.

The controller 130 may structure the number of columns included in the sub pre-decoding group according to the progress rate of the preliminary operation as in the preliminary operation speed information SPD_INF1 and SPD_INF2 illustrated in FIGS. 19 and 20.

FIG. 19 illustrates the structure of the preliminary operation speed information SPD_INF_1 in accordance with an embodiment of the present disclosure.

Referring to FIG. 19, each of a plurality of sub pre-decoding groups corresponding to a preliminary operation of the same number #ITR_PRE of iterations may include the same number of columns. Since the execution times T_PRE of sub-preliminary operations performed on the plurality of sub pre-decoding groups are the same as the unit time tCYCLE, the sub-preliminary operation speeds SPD for the plurality of sub pre-decoding groups may be the same.

For example, a first preliminary operation with the number #ITR_PRE of iterations of “1ST” may correspond to an “early stage” during a preliminary operation process. To perform the first preliminary operation, the controller 130 may divide 24 columns into 6 sub pre-decoding groups SUB_G1 to SUB_G6, as shown in FIGS. 18 and 19. The number nCOL of columns included in each of the sub pre-decoding groups SUB_G1 to SUB_G6 is 4, and the numbers of columns are all the same.

The controller 130 may perform the first preliminary operation on the 24 columns by performing first to sixth sub-preliminary operations on the first to sixth sub pre-decoding groups SUB_G1 to SUB_G6. The execution order of the first sub-preliminary operation may be first, the execution order of the second sub-preliminary operation may be second, and the execution order of the sixth sub-preliminary operation may be sixth.

When no predictive error information ERR_PRE is calculated by the first preliminary operation or the reliability of the calculated predictive error information ERR_PRE is low, the controller 130 may iteratively perform the preliminary operation. Accordingly, the controller 130 may perform the second preliminary operation with the number #ITR_PRE of iterations of “2ND”. In such a case, when the number of columns on which the decoding operation of the main operation unit 612 needs to be performed is insufficient, the second preliminary operation may not be iteratively performed. That is, the controller 130 may control the preliminary operation unit 622 so that the preliminary operation is performed on the next sub pre-decoding group.

The second preliminary operation with the number #ITR_PRE of iterations of “2ND” may correspond to a “mid-stage” during the preliminary operation process. To perform the second preliminary operation, the controller 130 may group the 24 columns into 3 sub pre-decoding groups SUB_G1 to SUB_G3. The number nCOL of columns included in each of the sub pre-decoding groups SUB_G1 to SUB_G3 is 8, and the numbers of columns are all the same. The controller 130 may perform the second preliminary operation on the 24 columns by performing the first to third sub-preliminary operations on the first to third sub pre-decoding groups SUB_G1 to SUB_G3.

When no predictive error information ERR_PRE is calculated by the second preliminary operation or the reliability of the calculated predictive error information ERR_PRE is low, the controller 130 may iteratively perform the preliminary operation. Accordingly, the controller 130 may perform the third preliminary operation with the number #ITR_PRE of iterations of “3RD”.

The third preliminary operation with the number #ITR_PRE of iterations of “3RD” may correspond to a “late stage” during the preliminary operation process. To perform the third preliminary operation, the controller 130 may group the 24 columns into two sub pre-decoding groups SUB_G1 and SUB_G2. The number nCOL of columns included in each of the sub pre-decoding groups SUB_G1 and SUB_G2 is 12, and the numbers of columns are all the same. The controller 130 may perform the third preliminary operation on the 24 columns by performing the first and second sub-preliminary operations on the first and second sub pre-decoding groups SUB_G1 and SUB_G2.

As illustrated in FIG. 19, the number nCOL of columns included in each of the plurality of sub pre-decoding groups may be proportional to the number #ITR_PRE of iterations of the preliminary operation, and the numbers of columns may be set to be equal to each other. The number N of a plurality of sub pre-decoding groups included in one preliminary operation may be inversely proportional to the number #ITR_PRE of iterations of a preliminary operation scheduled to be performed.

FIG. 20 illustrates the structure of the preliminary operation speed information SPD_INF2 in accordance with an embodiment of the present disclosure.

Referring to FIG. 20, the number nCOL of columns included in each of a plurality of sub pre-decoding groups corresponding to a preliminary operation of the same number #ITR_PRE of iterations may be set in proportion to the execution order of sub-preliminary operations. ‘A’ is the number of columns included in the second sub pre-decoding group SUB_G2 for which the second iteration of the preliminary operation performed. In other words, the second iteration of the preliminary operation may be performed in 8 columns.

For example, among six sub pre-decoding groups SUB_G1 to SUB_G6 on which a first preliminary operation with the number #ITR_PRE of iterations of “1ST” is performed, a fourth sub-preliminary operation performed on the fourth sub pre-decoding group SUB_G4 may be performed later than a third sub-preliminary operation performed on the third sub pre-decoding group SUB_G3. Accordingly, the number nCOL=5 of columns included in the fourth sub pre-decoding group SUB_G4 may be greater than the number nCOL=3 of columns included in the third sub pre-decoding group SUB_G3.

Since the execution times T_PRE of the sub-preliminary operations performed on the plurality of sub pre-decoding groups are the same as the unit time tCYCLE, the sub-preliminary operation speed SPD performed on each of the plurality of sub pre-decoding groups may increase in proportion to the order in which the sub-preliminary operations are performed.

In this way, the number nCOL of columns on which a sub-preliminary operation is performed during the unit time tCYCLE may increase in proportion to the number #ITR_PRE of iterations of a preliminary operation and the execution order of sub-preliminary operations.

That is, when the progress rate of the preliminary operation is an “early stage”, the number nCOL of columns on which the sub-preliminary operation is performed during the unit time tCYCLE may be set to the lowest, and may be set to increase toward a “late stage”. The number N of a plurality of sub pre-decoding groups may be inversely proportional to the number #ITR_PRE of iterations of a preliminary operation scheduled to be performed.

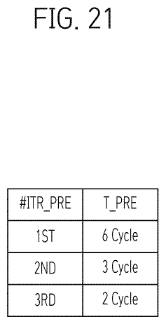

FIG. 21 illustrates an execution time T_PRE of a preliminary operation varying depending on the progress rate of the preliminary operation.

The execution time T_PRE of the preliminary operation means the time required for performing the preliminary operation on all 24 columns once. As the number #ITR_PRE of iterations of the preliminary operation increases, the execution time T_PRE of the preliminary operation decreases.

As described with reference to FIGS. 19 and 20, the first preliminary operation is performed on the six sub pre-decoding groups SUB_G1 to SUB_G6. The execution time T_PRE of a sub-preliminary operation performed on one sub pre-decoding group is the unit time tCYCLE. Accordingly, the execution time T_PRE of the first preliminary operation may be 6*tCYCLE.

The second preliminary operation is performed on three sub pre-decoding groups SUB_G. Accordingly, the execution time T_PRE of the second preliminary operation may be 3*tCYCLE.

The third preliminary operation is performed on the two sub pre-decoding groups SUB_G1 and SUB_G2. Accordingly, the execution time T_PRE of the third preliminary operation may be 2*tCYCLE.

The controller 130 may set the number nCOL of columns on which the preliminary operation has been performed during the unit time tCYCLE to be smaller as the number #ITR_PRE of iterations of a preliminary operation scheduled to be performed is lower. Since the execution time T_PRE of the preliminary operation for all the 24 columns increases, the preliminary operation speed SPD may be reduced as a result.

As the number #ITR_PRE of iterations of the preliminary operation scheduled to be performed is higher, the controller 130 may set the number nCOL of columns on which preliminary operations were performed during the unit time tCYCLE to be larger. Since the execution time T_PRE of the preliminary operation for all 24 columns is shortened, the preliminary operation speed SPD may be increased.

In the description of FIGS. 18 to 21, only setting the number nCOL of columns on which a preliminary operation is performed during the unit time tCYCLE is described based on the progress rate of preliminary operation; however, the embodiments of the present disclosure may re-set the number nCOL of columns on which a preliminary operation is performed during the unit time tCYCLE, based on the error rate ERR_MAIN.

For example, as illustrated in FIG. 20, when a second sub-preliminary operation A included in the second preliminary operation is completed, the controller 130 may determine that the progress rate of the preliminary operation has entered a “late phase”.

Accordingly, the controller 130 may compare an error rate ERR_MAIN calculated in a main decoding operation process recently performed with the threshold value TH. When the error rate ERR_MAIN exceeds the threshold value TH, the controller 130 may re-set the number nCOL of columns included in the third sub pre-decoding group SUB_G3 of the second preliminary operation to 8 or less instead of 9.

In this way, the number nCOL of columns included in the sub pre-decoding group SUB_G of the present disclosure may be varied not only by the progress rate of the preliminary operation but also by the error rate ERR_MAIN.

In such a case, the ‘remaining one column’ on which the third sub-preliminary operation has not been performed may be included in the first sub pre-decoding group SUB_G1 of the third preliminary operation with the number #ITR_PRE of iterations of “3RD”. Accordingly, the ‘remaining one column’ included in the third sub pre-decoding group SUB_G3 of the second preliminary operation may be subjected to a preliminary operation together with the first sub pre-decoding group SUB_G1 of the third preliminary operation. In this way, the already set number nCOL of columns included in the sub pre-decoding group SUB_G may be varied depending on the situation.

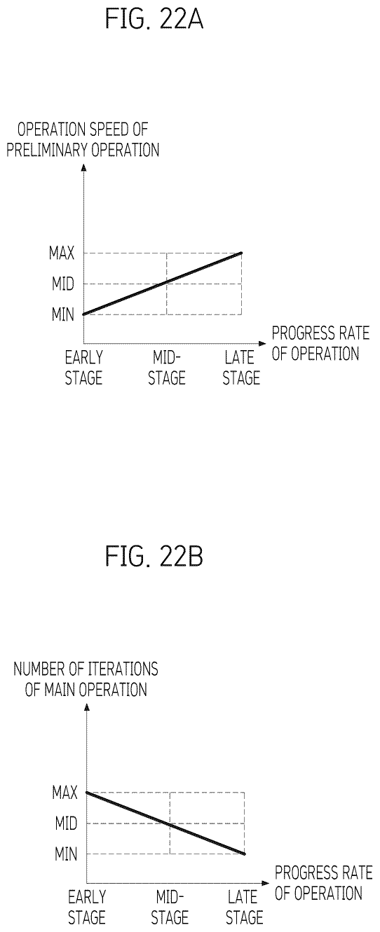

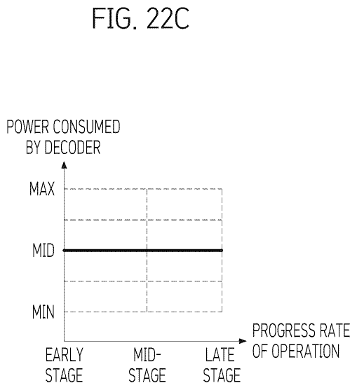

FIGS. 22A to 22C are graphs for describing energy consumption according to the progress rate of the decoding operation described with reference to FIGS. 14 to 21. A variable node VN described in the description of FIGS. 21A to 21C may correspond to the column described with reference to FIG. 18.

FIG. 22A describes the preliminary operation speed SPD according to the progress rate of the preliminary operation. The preliminary operation speed SPD may mean the number nVN of the variable nodes on which the preliminary operation is performed during the unit time tCYCLE.

When the progress rate of the preliminary operation is an “early stage”, the progress rate of the main decoding operation may also be an “early stage”. In the “early stage”, the reliability of the main decoding operation may be lower than in the “mid-stage”. The number of errors corrected by the main decoding operation may be small, and the number of errors that need to be corrected may be greater than in the “mid-stage”. In such a case, even though the preliminary operation unit 622 performs the preliminary operation at a high speed, the number nVN of the variable nodes over which the main decoding operation may be skipped may be less than in the “mid-stage” because there are no errors. Accordingly, the number nVN of the variable nodes stored in the task queue 632 may be greater than in “mid-stage”. That is, even though the number of preliminary operations performed per unit time tCYCLE is increased in the “early stage”, the efficiency of the main decoding operation is not sufficiently increased.

The controller 130 of the present disclosure may control the preliminary operation speed SPD to a minimum level MIN lower than in a “mid-stage” by setting the number of preliminary operations performed per unit time tCYCLE to be small. The amount of energy used for the preliminary operation may be proportional to the preliminary operation speed SPD. Accordingly, in the “early stage” of the decoding operation, the amount of energy used in the preliminary operation may reach the minimum level MIN.

When the progress rate of the preliminary operation is a “late stage”, the progress rate of the main decoding operation may also be a “late stage”. In the “late stage”, the reliability of the main decoding operation may be higher than in the “mid stage”. The number of errors corrected by the main decoding operation may be large, and the number of errors that need to be corrected may be less than in the “mid stage”. In such a case, when the preliminary operation unit 622 performs the preliminary operation at a high speed, the number nVN of the variable nodes over which the main decoding operation may be skipped may be greater than the in the “mid-stage” because there are no errors. Accordingly, the number nVN of the variable nodes stored in the task queue 632 may be less than in the “mid-stage”. That is, when the number of preliminary operations performed per unit time tCYCLE is increased in the “late stage”, the efficiency of the main decoding operation may be sufficiently increased.

Accordingly, the controller 130 of the present disclosure may control the preliminary operation speed SPD to a maximum level MAX higher than in the “mid-stage” by setting the number of preliminary operations performed per unit time tCYCLE to be large. Accordingly, in the “late stage” of the decoding operation, the amount of energy used for the preliminary operation may reach the maximum level MAX.

When the progress rate of the preliminary operation is a “mid-stage”, the number of the variable nodes nVN on which the preliminary operation is completed and the main decoding operation needs to be performed may be more than in the “early stage” and less than in the “late stage”. Accordingly, the controller 130 may control the preliminary operation speed SPD performed per unit time tCYCLE to a mid-level MID that is higher than in the “early stage” and lower than in the “late stage” of the decoding operation. In the “mid-stage” of the decoding operation, the amount of energy used in the preliminary operation may be the mid-level MID.

FIG. 22B describes the speed of the main decoding operation according to the progress rate of the main decoding operation.

When the progress rate of the main decoding operation is an “early stage”, the reliability of the main decoding operation may be lower than in the “mid-stage” and “late stage”. The number of errors corrected by the main decoding operation may be small, and the number of errors that need to be corrected may be greater than in the “mid-stage”. In the “early stage”, since the number of main decoding operations performed per unit time tCYCLE increases, the speed of the main decoding operation may reach the maximum level MAX. Accordingly, in the “late stage”, the amount of energy used in the main decoding operation may reach the maximum level MAX.

When the progress rate of the main decoding operation is a “late stage”, the reliability of the main decoding operation may be higher than in the “mid-stage” and the “late stage”. The number of errors corrected by the main decoding operation may be large, and the number of errors that need to be corrected may be less than in the “mid-stage”. Due to the preliminary operation, the number nVN of the variable nodes over which the main decoding operation may be skipped may be greater than in the “mid-stage”. In the “late stage”, since the number of main decoding operations performed per unit time tCYCLE decreases, the speed of the main decoding operation may reach the minimum level MIN. Accordingly, in the “late stage”, the amount of energy used in the main decoding operation may reach the minimum level MIN.

When the progress rate of the main decoding operation is a “mid-stage”, the reliability of the main decoding operation, the number of errors corrected by the main decoding operation, and the number nVN of the variable nodes over which the main decoding operation may be skipped due to the preliminary operation may higher than in the “early stage” and less than in the “late stage”. The number of errors that need to be corrected may be less than in the “early stage” and more than in the “late stage”. In the “mid-stage”, the number of main decoding operations performed per unit time tCYCLE may reach the mid-level MID. Accordingly, the speed of the main decoding operation and the amount of energy used in the main decoding operation may reach the mid-level MID.

FIG. 22C illustrates energy consumed by the LDPC decoder 600B according to the progress rate of a decoding operation.

Referring to FIGS. 22A to 22C, when the progress rate of the decoding operation is an “early stage”, the preliminary operation speed SPD is a minimum level MIN, and the speed according to the number nITR of iterations of the main decoding operation is a maximum level MAX. Accordingly, the amount of energy consumed by the preliminary operation unit 622 may reach the minimum level MIN, and the amount of energy consumed by the main operation unit 612 may reach the maximum level MAX. Accordingly, the amount of energy consumed by the LDPC decoder 600B may reach a mid-level MID.

When the progress rate of the decoding operation is a “mid-stage”, the preliminary operation speed SPD is the mid-level MID, and the speed according to the number nITR of iterations of the main decoding operation is the mid-level MID. Accordingly, the amount of energy consumed by the preliminary operation unit 622 may reach the mid-level MID, and the amount of energy consumed by the main operation unit 612 may reach the mid-level MID. Accordingly, the amount of energy consumed by the LDPC decoder 600B may reach the mid-level MID.

When the progress rate of the decoding operation is a “late stage”, the preliminary operation speed SPD is the maximum level MAX, and the speed according to the number nITR of iterations of the main decoding operation is the minimum level MIN. Accordingly, the amount of energy consumed by the preliminary operation unit 622 may reach the maximum level MAX, and the amount of energy consumed by the main operation unit 612 may reach the minimum level MIN. Accordingly, the amount of energy consumed by the LDPC decoder 600B may reach the mid-level MID.

In this way, the amount of energy consumed by the LDPC decoder 600B in accordance with an embodiment of the present disclosure may be maintained at the mid-level MID regardless of the progress rate of a decoding operation.

Since the amount of energy consumed by the LDPC decoder 600B is uniform, the controller 130 may stably operate without malfunction or performance degradation. Additionally, no overload may occur in the power supply or circuit of the controller 130. Accordingly, the power supply may not turn off the power or forcibly lower the voltage. Consequently, the LDPC decoder 600B may operate predictably and consistently at the designed optimal performance.

While the embodiments of the present disclosure have been illustrated and described with respect to the specific embodiments, it will be apparent to those skilled in the art in light of the present disclosure that various changes and modifications may be made without departing from the spirit and scope of the disclosure as defined in the following claims. Furthermore, the embodiments may be combined to form additional embodiments.

What is claimed is:

1. A method for decoding a memory system, the method comprising:
establishing a plurality of check nodes and a plurality of variable nodes corresponding to the plurality of check nodes of a codeword;
setting a preliminary operation speed based on a progress rate of a preliminary operation for generating predictive error information of each of the plurality of the variable nodes;
performing the preliminary operation according to the preliminary operation speed; and
performing a main decoding operation for error correction on at least a part of the plurality of the variable nodes based on the predictive error information.

2. The method of claim 1, wherein the setting of the preliminary operation speed includes differently setting the number of the variable nodes, on which the preliminary operation is performed during a unit time, according to the progress rate of the preliminary operation.

3. The method of claim 1, wherein the progress rate of the preliminary operation includes the number of iterations of the preliminary operation and an execution order of a plurality of sub-preliminary operations included in the preliminary operation.

4. The method of claim 1, wherein the setting of the preliminary operation speed includes:
dividing the plurality of the variable nodes into first to N^{th} groups;
corresponding first to N^{th} sub-preliminary operations included in the preliminary operation to the first to N^{th} groups, respectively; and
setting execution times of the first to N^{th} sub-preliminary operations to be equal to one another,
wherein N is inversely proportional to the number of iterations of the preliminary operation.

5. The method of claim 4, wherein the numbers of the variable nodes respectively included in the first to N^{th} groups are proportional to the number of iterations of the preliminary operation and are equal to one another.

6. The method of claim 4, wherein the number of the variable nodes included in each of the first to N^{th} groups is proportional to the number of iterations of the preliminary operation and an execution order of the first to N^{th} sub-preliminary operations.

7. The method of claim 1, further comprising:
re-setting a preliminary operation speed of a preliminary operation scheduled to be performed, according to an error rate calculated during the performing of the main decoding operation.

8. The method of claim 7, wherein the error rate includes at least one of the number of unsatisfied check nodes calculated during the error correction, the number of iterations of the main decoding operation performed during the error correction, and the number of uncorrectable errors.

9. The method of claim 7, wherein the re-setting of the preliminary operation speed includes:
comparing the error rate with a threshold value; and
re-setting the preliminary operation speed to be lower than a speed of an immediately preceding preliminary operation, or to be higher than a speed set for the preliminary operation speed of the preliminary operation scheduled to be performed according to the comparison result.

10. The method of claim 7, wherein performing the preliminary operation comprises
determining to re-set the preliminary operation speed when the progress rate of the preliminary operation is greater than or equal to a specific value.

11. A memory system comprising:
a memory device configured to output a codeword read from a plurality of memory cells; and
a controller configured to:
set a preliminary operation speed, based on a progress rate of the preliminary operation for generating predictive error information of each of a plurality of the variable nodes,
perform the preliminary operation according to the preliminary operation speed, and
perform a main decoding operation for error correction on at least a part of the plurality of the variable nodes based on the predictive error information.

12. The memory system of claim 11, wherein the controller includes a preliminary operation unit including a plurality of unit preliminary operation units for performing the preliminary operation, and
sets the preliminary operation speed by varying the number of a plurality of unit preliminary operation units driven during a unit time.

13. The memory system of claim 11, wherein the progress rate of the preliminary operation includes the number of iterations of the preliminary operation and an execution order of a plurality of sub-preliminary operations included in the preliminary operation.

14. The memory system of claim 11, wherein: the plurality of the variable nodes includes first to N^{th} groups corresponding to first to N^{th} sub-preliminary operations included in the preliminary operation,
N is inversely proportional to the number of iterations of the preliminary operation, and
execution times of the first to N^{th} sub-preliminary operations are equal to one another.

15. The memory system of claim 14, wherein the numbers of the variable nodes respectively included in the first to N^{th} groups are proportional to the number of iterations of the preliminary operation and are equal to one another.

16. The memory system of claim 14, wherein the number of the variable nodes included in each of the first to N^{th} groups is proportional to the number of iterations of the preliminary operation and an execution order of the first to N^{th} sub-preliminary operations.

17. The memory system of claim 11, wherein the controller re-sets a preliminary operation speed of a preliminary operation scheduled to be performed, based on main error information calculated during the main decoding operation.

18. The memory system of claim 17, wherein the main error information includes at least one of the number of unsatisfied check nodes calculated during the error correction, the number of iterations of the main decoding operation performed during the error correction, and the number of uncorrectable errors.

19. The memory system of claim 17, wherein the controller re-sets the preliminary operation speed to be lower than a speed of an immediately preceding preliminary operation, or to be higher than a speed set for the preliminary operation speed of the preliminary operation scheduled to be performed, according to a result of comparing the main error information with a threshold value.

20. The memory system of claim 17, wherein, when the progress rate of the preliminary operation is greater than or equal to a specific value, the controller determines to re-set the preliminary operation speed.
